(19) United States
(12) Patent Application Publication
(10) Pub. No.: US 2026/0013133 A1
(43) Pub. Date: Jan. 8, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventor: Jun Hyeok HAN, Suwon-si (KR)

(73) Assignee: Samsung Electronics Co., Ltd., Suwon-si (KR)

(21) Appl. No.: 19/080,406

(22) Filed: Mar. 14, 2025

(30) Foreign Application Priority Data
Jul. 5, 2024 (KR) 10-2024-0088807

(51) Int. Cl. H10B 43/27; G11C 16/04; H01L 23/00; H01L 25/18; H10B 43/10; H10B 43/35; H10B 43/40; H10B 80/00; H10D 80/30

(52) U.S. Cl. CPC H10B 43/27; G11C 16/0483; H01L 24/08; H01L 25/18; H10B 43/10; H10B 43/35; H10B 43/40; H10B 80/00; H10D 80/30; H01L 24/32; H01L 2224/08145; H01L 2224/32145; H01L 2224/32225; H01L 2225/06524; H01L 2924/1438

(57) ABSTRACT

There is provided a semiconductor memory device that has improved performance and/or reliability. The semiconductor memory device includes a substrate, a stacked structure including a plurality of gate electrodes stacked on the substrate and spaced apart from each other in a first direction, the first direction being perpendicular to an upper surface of the substrate, a channel structure extending in the first direction and crossing the plurality of gate electrodes, and a dam structure extending in the first direction and surrounding at least a portion of the stacked structure in a plan view, on the substrate. A height of an upper surface of the dam structure from the upper surface of the substrate is lower than a height of the channel structure from the upper surface of the substrate.

### CROSS-REFERENCE TO RELATED APPLICATION

This application claims priority from Korean Patent Application No. 10-2024-0088807 filed on Jul. 5, 2024 in the Korean Intellectual Property Office and all the benefits accruing therefrom under 35 U.S.C. 119, the contents of which in its entirety are herein incorporated by reference.

### BACKGROUND

Some example embodiments relate to a semiconductor memory device and an electronic system including the same, and more particularly, to a semiconductor memory device including memory cells arranged three-dimensionally, and an electronic system including the same.

As semiconductor memory devices capable of storing high capacity data are desired in electronic systems, methods capable of increasing data storage capacity of semiconductor memory devices have been studied. Some methods capable of increasing data storage capacity of a semiconductor memory devices may include semiconductor memory devices including memory cells that are arranged three-dimensionally.

### SUMMARY

Some example embodiments of the present disclosure provide a semiconductor memory device with improved performance and/or reliability.

Some example embodiments of the present disclosure provide an electronic system including a semiconductor memory device having improved performance and/or reliability.

Example embodiments of the present disclosure are not limited to those mentioned above, and additional example embodiments of the present disclosure, may be clearly understood by those skilled in the art from the following description of the present disclosure.

According to some example embodiments of the present disclosure, there is provided a semiconductor memory device comprising a substrate, a stacked structure including a plurality of gate electrodes stacked on the substrate and spaced apart from each other in a first direction, the first direction being perpendicular to an upper surface of the substrate, a channel structure extending in the first direction and crossing the plurality of gate electrodes, and a dam structure extending in the first direction and surrounding at least a portion of the stacked structure in a plan view, on the substrate. A height of an upper surface of the dam structure from the upper surface of the substrate is lower than a height of the channel structure from the upper surface of the substrate.

According to some example embodiments of the present disclosure, there is provided a semiconductor memory device comprising a substrate, a stacked structure including a plurality of gate electrodes stacked on the substrate and spaced apart from each other in a first direction, the first direction being perpendicular to an upper surface of the substrate, an interlayer insulating layer surrounding the stacked structure on the substrate, a first channel structure extended in the first direction through the interlayer insulating layer and the stacked structure, a dam structure extending in the first direction and surrounding at least a portion of the stacked structure in a plan view, a capping insulating layer on the interlayer insulating layer, the first channel structure, and the dam structure, and a second channel structure connected to the first channel structure, the second channel structure passing through the capping insulating layer. The dam structure is spaced apart from the capping insulating layer.

According to some example embodiments of the present disclosure, there is provided an electronic system comprising a main board, a semiconductor memory device including a peripheral circuit structure and a memory cell structure, the peripheral circuit structure and the memory cell structure being sequentially stacked on the main board, and a controller electrically connected to the semiconductor memory device on the main board. The memory cell structure includes a stacked structure including a plurality of gate electrodes stacked on the peripheral circuit structure and spaced apart from each other in a first direction, a channel structure extending in the first direction and crossing the plurality of gate electrodes, a gate contact passing through the stacked structure, a dam structure spaced part from the gate contact in a second direction, the second direction crossing the first direction, the dam structure surrounding at least a portion of the stacked structure in a plan view, an interlayer insulating layer covering the stacked structure, the channel structure, and the gate contact, and a height of a lower surface of the dam structure from a lower surface of the peripheral circuit structure is higher than a height of a lower surface of the channel structure from a lower surface of the peripheral circuit structure.

### BRIEF DESCRIPTION OF THE DRAWINGS

FIG. 1 is an example block diagram illustrating a semiconductor memory device according to some example embodiments of the present disclosure.

FIG. 2 is an example circuit view illustrating a semiconductor memory device according to some example embodiments of the present disclosure.

FIG. 3 is a layout view illustrating a semiconductor memory device according to some example embodiments.

FIG. 4 is a cross-sectional view taken along line A-A′ of FIG. 3.

FIG. 5 is an enlarged view illustrating a region P of FIG. 4.

FIG. 6 is an enlarged view illustrating a region Q of FIG. 4.

FIG. 7 is a view illustrating a semiconductor memory device according to some example embodiments of the present disclosure.

FIG. 8 is an enlarged view illustrating a region R of FIG. 7.

FIGS. 9 to 21 are views illustrating intermediate steps to describe a method for fabricating a semiconductor memory device according to some example embodiments.

FIGS. 22 to 25 are views illustrating intermediate steps to describe a method for fabricating a semiconductor memory device according to some example embodiments.

FIG. 26 is an example block diagram illustrating an electronic system according to some example embodiments of the present disclosure.

FIG. 27 is an example perspective view illustrating an electronic system according to some example embodiments of the present disclosure.

FIG. 28 is a schematic cross-sectional view taken along line I-I of FIG. 27.

### DETAILED DESCRIPTION

It will be understood that, although the terms “first,” “second,” etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. Also, a lower element or component discussed below could be termed an upper element or component without departing from the technical spirits of the present disclosure.

Spatially relative terms, such as “below,” “beneath,” “lower,” “above” and “upper,” may be used herein to easily describe relationship between one element or component and another element(s) or element(s) as shown in the drawings. It is to be understood that the spatially relative terms are intended to encompass different orientations of elements in use or operation in addition to the orientation depicted in the drawings. For example, when the element shown in the drawings is turned over, elements described as “below” or “beneath” other elements would then be oriented “above” the other elements. Thus, the example term “below” can encompass both orientations of above and below. The element may be otherwise oriented, and accordingly, the spatially relative terms may be interpreted depending on the orientations.

Hereinafter, some example embodiments of the present disclosure will be described with reference to the accompanying drawings. The same reference numerals will be used for the same elements on the drawings, and their redundant description may be omitted

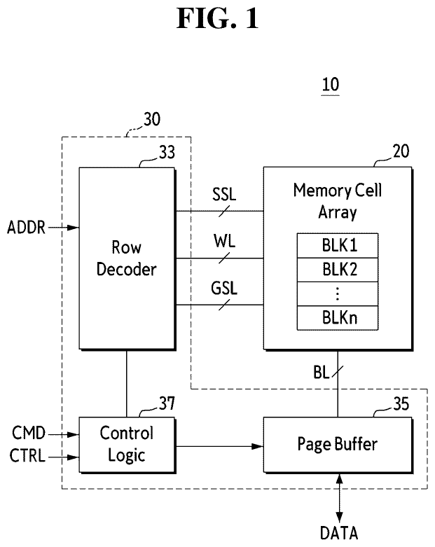

Hereinafter, a semiconductor memory device according to some example embodiments of the present disclosure will be described with reference to FIGS. 1 to 6.

FIG. 1 is an example block diagram illustrating a semiconductor memory device according to some example embodiments of the present disclosure.

A memory cell array 20 may include a plurality of memory cell blocks BLK1 to BLKn. Each of the memory cell blocks BLK1 to BLKn may include a plurality of memory cells. The memory cell array 20 may be connected to a peripheral circuit 30 through a bit line BL, a word line WL, at least one string selection line SSL and at least one ground selection line GSL. In detail, the memory cell blocks BLK1 to BLKn may be connected to a row decoder 33 through the word line WL, the string selection line SSL and the ground selection line GSL. In addition, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data DATA to and from an external device of the semiconductor memory device 10. The peripheral circuit 30 may include a control logic 37, a row decoder 33 and a page buffer 35. Although not shown, the peripheral circuit 30 may further include various sub-circuits such as an input/output circuit, a voltage generating circuit for generating various voltages for an operation of the semiconductor memory device 10 and an error correction circuit for correcting an error of the data DATA read from the memory cell array 20.

The control logic 37 may be connected to the row decoder 33, the input/output circuit and the voltage generating circuit. The control logic 37 may control the overall operation of the semiconductor memory device 10. The control logic 37 may generate various internal control signals used in the semiconductor memory device 10 in response to the control signal CTRL. For example, the control logic 37 may adjust a voltage level provided to the word line WL and the bit line BL when a memory operation such as a program operation or an erase operation is performed.

The row decoder 33 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. In addition, the row decoder 33 may transfer a voltage for performing the memory operation to the word line WL of the selected memory cell blocks BLK1 to BLKn.

The page buffer 35 may be connected to the memory cell array 20 through the bit line BL. The page buffer 35 may operate as a write driver or a sense amplifier. In detail, when a program operation is performed, the page buffer 35 may operate as a write driver to apply a voltage according to the data DATA to be stored in the memory cell array 20, to the bit line BL. Meanwhile, when a read operation is performed, the page buffer 35 may operate as a sense amplifier to sense the data DATA stored in the memory cell array 20.

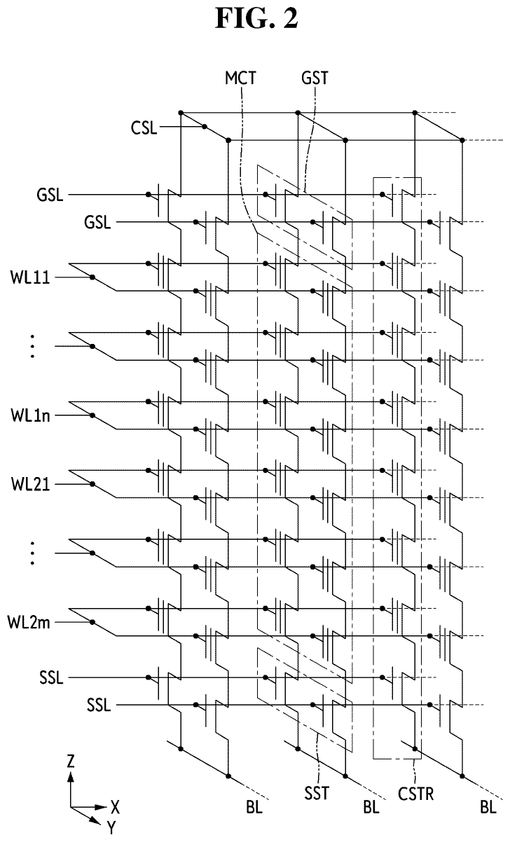

FIG. 2 is an example circuit view illustrating a semiconductor memory device according to some example embodiments of the present disclosure.

Referring to FIG. 2, a memory cell array (e.g., 20 of FIG. 1) of a semiconductor memory device according to some example embodiments includes a common source line CSL, a plurality of bit lines BL and a plurality of cell strings CSTR.

The plurality of bit lines BL may be arranged two-dimensionally on a plane including a first direction X and a second direction Y. For example, the bit lines BL may be respectively extended in the second direction Y, and may be spaced apart from each other and then arranged along the first direction X. The plurality of cell strings CSTR may be connected to the respective bit lines BL in parallel. The cell strings CSTR may be commonly connected to the common source line CSL. That is, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL and a plurality of memory cell transistors MCT disposed between the ground selection transistor GST and the string selection transistor SST. Each of the memory cell transistors MCT may include a data storage element. The ground selection transistor GST, the string selection transistor SST, and the memory cell transistors MCT may be connected in series in a vertical direction (hereinafter, referred to as a third direction Z) crossing the first direction X and the second direction Y.

The common source line CSL may be commonly connected to sources of the ground selection transistors GST. In addition, the ground selection line GSL, a plurality of word lines WL11 to WL1n and WL21 to WL2m and the string selection line SSL may be disposed between the common source line CSL and the bit line BL. The ground selection line GSL may be used as a gate electrode of the ground selection transistor GST, the word lines WL11 to WL1n and WL21 to WL2m may be used as gate electrodes of the memory cell transistors MCT, and the string selection line SSL may be used as a gate electrode of the string selection transistor SST.

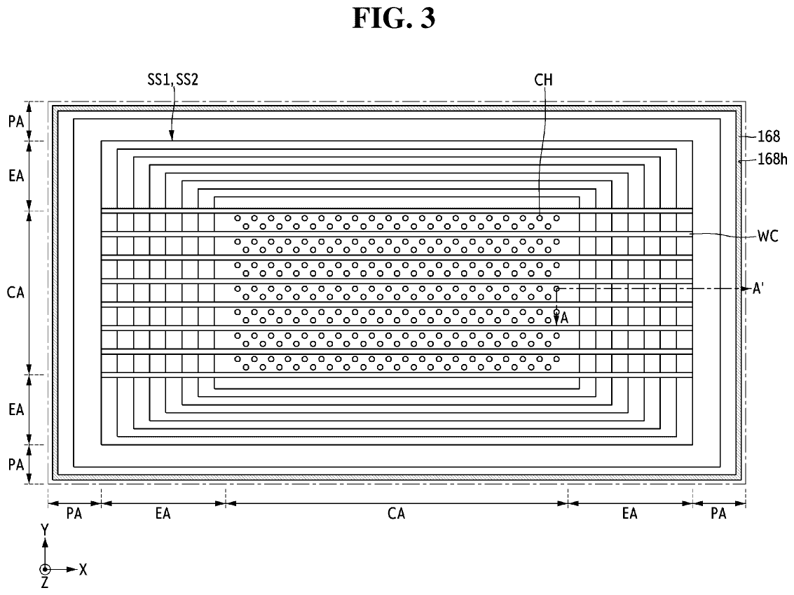

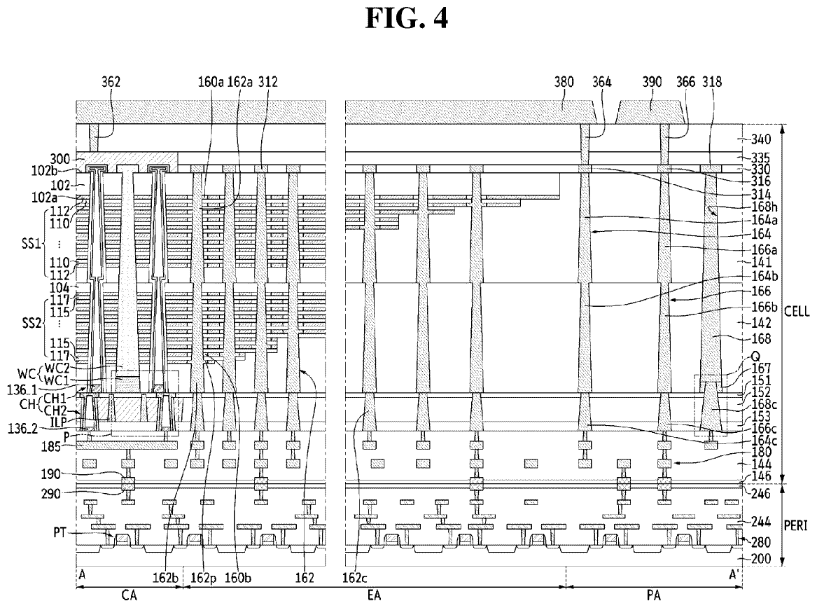

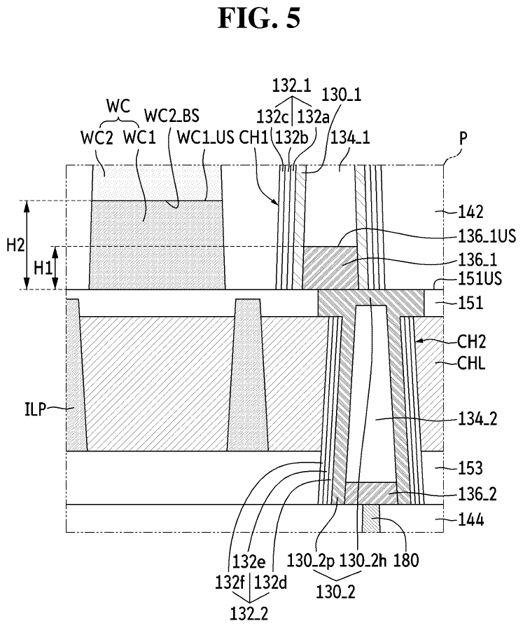

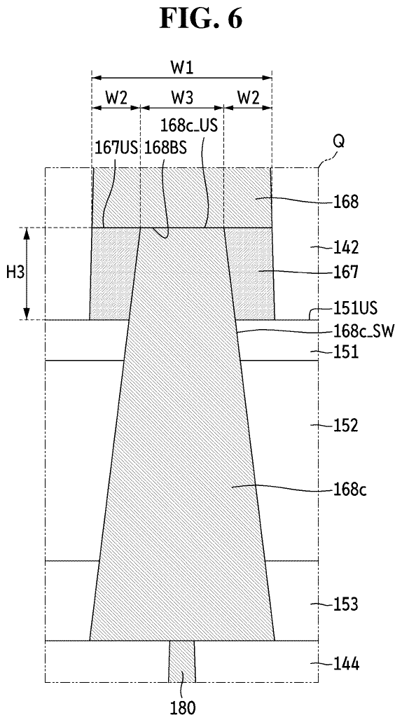

FIG. 3 is a layout view illustrating a semiconductor memory device according to some example embodiments. FIG. 4 is a cross-sectional view taken along line A-A′ of FIG. 3. FIG. 5 is an enlarged view illustrating a region P of FIG. 4. FIG. 6 is an enlarged view illustrating a region Q of FIG. 4.

Referring to FIGS. 3 to 6, the semiconductor memory device according to some example embodiments includes a memory cell structure CELL and a peripheral circuit structure PERI.

The memory cell structure CELL may include a cell array area CA, an extension area EA, and an outer area PA.

A memory cell array (e.g., 20 of FIG. 1) including a plurality of memory cells may be formed in the cell array area CA. For example, a channel structure CH, gate electrodes 112 and 117, a conductive line 185 and a source layer 300, which will be described later, may be disposed on the cell array area CA.

The extension area EA may be disposed near the cell array area CA. For example, the extension area EA may be adjacent to the cell array area CA in the first direction X. The gate electrodes 112 and 117, which will be described later, may be stacked on the extension area EA in a stepwise shape.

The outer area PA may be a peripheral area surrounding the cell array area CA and the extension area EA. For example, the outer area PA may be adjacent to the cell array area CA and/or the extension area EA in the first direction X and the second direction Y. A conductive pad 390, which will be described later, may be disposed in the outer area PA.

The memory cell structure CELL may include a first base insulating layer 102, a first stacked structure SS1, a first interlayer insulating layer 141, a second base insulating layer 104, a second stacked structure SS2, a second interlayer insulating layer 142, a channel structure CH, a division pattern WC, an insertion insulating pattern ILP, a first capping insulating layer 151, a second capping insulating layer 152, a third capping insulating layer 153, a gate contact 162, a first through via 164, a second through via 166, a lower contact 162c, a first via contact 164c, a second via contact 166c, a dam structure 168, an insulating pattern 167, a dam contact 168c, a first wiring structure 180, a source layer 300, a pad insulating layer 330, a first upper insulating layer 335, a second upper insulating layer 340, a connection pattern 380, and a conductive pad 390.

The first base insulating layer 102 may form an insulating area over the cell array area CA and the extension area EA. The first base insulating layer 102 may include at least one of, for example, silicon oxide, silicon nitride and/or silicon oxynitride, but is not limited thereto. For example, the first base insulating layer 102 may include a silicon oxide layer.

The first base insulating layer 102 may include a first surface 102a and a second surface 102b, which are opposite to each other. Each of the first surface 102a and the second surface 102b may be extended along a horizontal plane (e.g., XY plane). In the following description, the first surface 102a may be referred to as a lower surface of the first base insulating layer 102, and the second surface 102b may be referred to as an upper surface of the first base insulating layer 102.

The first stacked structure SS1 may be disposed on the lower surface of the first base insulating layer 102. The first stacked structure SS1 may include a plurality of first mold insulating layers 110 and a plurality of first gate electrodes 112, which are alternately stacked on the lower surface of the first base insulating layer 102. Each of the first mold insulating layers 110 and each of the first gate electrodes 112 may have a layered structure extended along a horizontal plane (e.g., XY plane). The first gate electrodes 112 may be sequentially stacked by being spaced apart from each other by the first mold insulating layers 110.

The first gate electrodes 112 of the cell array area CA may be further extended into the extension area EA. The first gate electrodes 112 of the extension area EA may be stacked on the first base insulating layer 102 in a stepwise shape. For example, in the extension area EA, a length of the first gate electrodes 112 extended in the first direction X may be reduced as the first gate electrodes 112 become far away from the first base insulating layer 102.

In some example embodiments, the first gate electrodes 112 may include at least one ground selection line (e.g., GSL of FIG. 2) and a plurality of first word lines (e.g., WL11 to WL1n of FIG. 2), which are sequentially stacked on the lower surface of the first base insulating layer 102. The number and shape of the first mold insulating layers 110 and the first gate electrodes 112 are only for example, and are not limited to the example as shown.

The first interlayer insulating layer 141 may cover the first base insulating layer 102 and the first stacked structure SS1. The first interlayer insulating layer 141 may contain at least one of, for example, silicon oxide, silicon oxynitride and/or a low dielectric constant (low-k) material having a dielectric constant lower than that of silicon oxide, but example embodiments are not limited thereto.

The second base insulating layer 104 may be formed on a lower surface of the first interlayer insulating layer 141. The second base insulating layer 104 may form an insulating area the cell array area CA and the extension area EA. The second base insulating layer 104 may include at least one of, for example, silicon oxide, silicon nitride and/or silicon oxynitride, but example embodiments are not limited thereto. For example, the second base insulating layer 104 may include a silicon oxide layer.

The second stacked structure SS2 may be formed on a lower surface of the second base insulating layer 104. The second stacked structure SS2 may include a plurality of second mold insulating layers 115 and a plurality of second gate electrodes 117, which are alternately stacked on the lower surface of the second base insulating layer 104. Each of the second mold insulating layers 115 and each of the second gate electrodes 117 may have a layered structure in which they are extended along a horizontal plane (e.g., XY plane). The second gate electrodes 117 may be sequentially stacked by being spaced apart from each other by the second mold insulating layers 115.

The second gate electrodes 117 of the cell array area CA may be further extended into the extension area EA. The second gate electrodes 117 of the extension area EA may be stacked on the second base insulating layer 109 in a stepwise shape. For example, in the extension area EA, a length of the second gate electrodes 117 extending in the first direction X may be reduced as the second gate electrodes 117 become far away from the second base insulating layer 109.

In some example embodiments, the second gate electrodes 117 may include a plurality of second word lines (e.g., WL21 to WL2m of FIG. 2) and at least one string selection line (e.g., SSL of FIG. 2), which are sequentially stacked on a lower surface of the second base insulating layer 109. The number and shape of the second mold insulating layers 115 and the second gate electrodes 117 are only example, and example embodiments are not limited to the shown example.

The second interlayer insulating layer 142 may cover the second base insulating layer 104 and the second stacked structure SS2. The second interlayer insulating layer 142 may contain at least one of, for example, silicon oxide, silicon oxynitride and/or a low dielectric constant (low-k) material having a dielectric constant lower than that of silicon oxide, but example embodiments are not limited thereto.

Each of the gate electrodes 112 and 117 may contain a conductive material, for example, metal such as tungsten (W), molybdenum (Mo), ruthenium (Ru), cobalt (Co) and nickel (Ni) or a semiconductor material such as silicon, but example embodiments are not limited thereto. For example, each of the gate electrodes 112 and 117 may contain at least one of a tungsten (W) film, a molybdenum (Mo) film and/or a ruthenium (Ru) film.

Each of the mold insulating layers 110 and 115 may include at least one of, for example, silicon oxide, silicon nitride and/or silicon oxynitride, but example embodiments are not limited thereto. For example, each of the mold insulating layers 110 and 115 may include a silicon oxide layer.

Although two stacked structures SS1 and SS2 are shown as being stacked, this is only for example, and the number of the stacked structures SS1 and SS2 may be three or more.

The channel structure CH may be disposed in the cell array area CA. The channel structure CH may include a first channel structure CH1 and a second channel structure CH2.

The first channel structure CH1 may be extended in the third direction Z to pass through the stacked structures SS1 and SS2. The first channel structure CH1 may cross the plurality of gate electrodes 112 and 117. For example, the first channel structure CH1 may be a pillar-shaped structure (e.g., a cylinder-shaped structure) extending in the third direction Z.

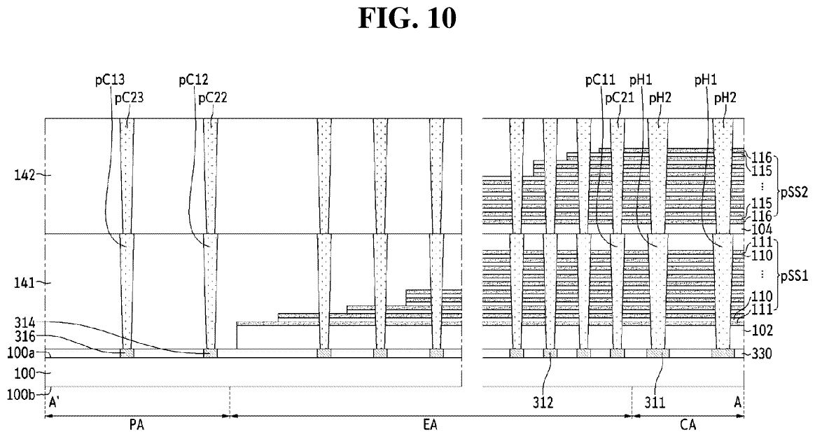

In some example embodiments, a plurality of channel structures CH may be arranged in a zigzag shape. For example, as shown in FIG. 10, the first channel structures CH1 may be arranged alternately with each other in the first direction X and the second direction Y. The first channel structures CH1 may further improve the degree of integration of the semiconductor memory device. The number and arrangement of the first channel structures CH1 are only for example, and example embodiments are not limited to the shown example.

In some example embodiments, each of the first channel structures CH1 may have a step difference between the first stacked structure SS1 and the second stacked structure SS2. For example, as shown in FIG. 4, the sides of each of the first channel structures CH1 may have a bending portion at a boundary between the first interlayer insulating layer 141 and the second base insulating layer 104.

Each of the first channel structures CH1 may include a first semiconductor film 130_1 and a first data storage film 132_1.

The first semiconductor film 130_1 may be extended in the third direction Z to cross the plurality of gate electrodes 112 and 117. Although the first semiconductor film 130_1 is shown as having only a cup shape, this is only for example. For example, the first semiconductor film 130_1 may have various shapes such as a cylindrical shape, a quadrangular barrel shape and a filled pillar shape. The first semiconductor film 130_1 may contain, for example, a semiconductor material such as monocrystalline silicon, polycrystalline silicon, an organic semiconductor material and a carbon nanostructure, but example embodiments are not limited thereto.

The first data storage film 132_1 may be interposed between the first semiconductor film 130_1 and the plurality of gate electrodes 112 and 117. For example, the first data storage film 132_1 may be extended along an outer side of the first semiconductor film 130_1. For example, the first data storage film 132_1 may contain at least one of silicon oxide, silicon nitride, silicon oxynitride or a high dielectric constant material having a dielectric constant higher than that of silicon oxide, but example embodiments are not limited thereto. The high dielectric constant material may contain, for example, at least one of aluminum oxide, hafnium oxide, lanthanum oxide, tantalum oxide, titanium oxide, lanthanum hafnium oxide, lanthanum aluminum oxide, dysprosium scandium oxide or their combination.

In some example embodiments, the first data storage film 132_1 may be formed of multiple layers. For example, as shown in FIG. 5, the first data storage film 132_1 may include a first tunnel insulating film 132a, a first charge storage film 132b and a first blocking insulating film 132c, which are sequentially stacked on the outer side of the first semiconductor film 130_1.

The first tunnel insulating film 132a may contain, for example, silicon oxide or a high dielectric constant material (e.g., aluminum oxide (Al₂O₃) or hafnium oxide (HfO₂)) having a dielectric constant higher than that of silicon oxide. The first charge storage film 132b may include, for example, silicon nitride. The first blocking insulating film 132c may contain, for example, silicon oxide or a high dielectric constant material (e.g., aluminum oxide (Al₂O₃) or hafnium oxide (HfO₂)) having a dielectric constant higher than that of silicon oxide. However, example embodiments are not limited thereto.

In some example embodiments, the first semiconductor film 130_1 may be protrude upward more than the first stacked structure SS1 and the first data storage film 132_1. For example, one end (e.g., upper end) of the first semiconductor film 130_1 may be formed to be higher than an upper surface of the first stacked structure SS1 and an upper surface of the first data storage film 132_1.

In some example embodiments, the first channel structure CH1 may further include a first filling insulating layer 134_1. The first filling insulating layer 134_1 may be formed to fill the inside of the cup-shaped first semiconductor film 130_1. The first filling insulating layer 134_1 may contain an insulating material, for example, silicon oxide, but example embodiments are not limited thereto.

In some example embodiments, the first channel structure CH1 may further include a first channel pad 136_1. The first channel pad 136_1 may be formed to be connected to the other end (e.g., a lower end) of the first semiconductor film 130_1. The first channel pad 136_1 may be disposed on the first filling insulating layer 134_1. The first channel pad 136_1 may be in contact with the first filling insulating layer 134_1. The first channel pad 136_1 may contain a conductive material, for example, polysilicon doped with impurities, metal, or metal silicide, but example embodiments are not limited thereto.

Although not shown, in some example embodiments, a dummy channel structure may be formed in the extension area EA. The dummy channel structure may be extended in the third direction Z to pass through at least a portion of the stacked structures SS1 and SS2.

The dummy channel structure may be formed at the same level as the first channel structure CH1, or may be formed at a different level from the first channel structure CH1. For example, when the dummy channel structure is formed at the same level as the first channel structure CH1, the dummy channel structure may include the first semiconductor film 130_1, the first data storage film 132_1, the first filling insulating layer 134_1 and the first channel pad 136_1. For another example, when the dummy channel structure is formed at a different level from the first channel structure, the dummy channel structure may be filled with an insulating material and/or a conductive material. A size (e.g., a width) of the dummy channel structure may be the same as that of the first channel structure CH1, or may be different from that of the first channel structure CH1. In some example embodiments, the size of the dummy channel structure may be larger than that of the first channel structure CH1.

The second channel structure CH2 may be disposed on a lower surface of the first channel structure CH1. The second channel structure CH2 may be connected to the first channel structure CH1. In the third direction Z, the second channel structure CH2 may include a portion that overlaps the first channel structure CH1 and a portion that does not overlap the first channel structure CH1. That is, when viewed in a plan view, the second channel structure CH2 may overlap a portion of the first channel structure CH1.

The second channel structure CH2 may be disposed on a lower surface of the second interlayer insulating layer 142. The second channel structure CH2 may be disposed in the first capping insulating layer 151, a channel layer CHL, and the third capping insulating layer 153.

The first capping insulating layer 151 and the third capping insulating layer 153 may contain an insulating material. The channel layer CHL may contain the same material as that of the first semiconductor film 130_1, but example embodiments are not limited thereto. The channel layer CHL may be disposed at the same level as the second capping insulating layer 152. The first to third capping insulating layers 151, 152 and 153 may cover the stacked structures SS1 and SS2, the channel structure CH, and the dam structure 168.

The second channel structure CH2 may include a second semiconductor film 130_2 and a second data storage film 132_2.

The second semiconductor film 130_2 may include a horizontal portion 130_2h and a vertical portion 130_2p. The horizontal portion 130_2h may be in contact with the first channel structure CH1. The horizontal portion 130_2h may be connected to the first channel pad 136_1, the first semiconductor film 130_1, and the first data storage film 132_1, and the vertical portion 130_2p may be extended from the horizontal portion 130_2h in the third direction Z.

The second data storage film 132_2 may be disposed on the horizontal portion 130_2h and the vertical portion 130_2p of the second semiconductor film 130_2. The second data storage film 132_2 may be extended along an outer side of the vertical portion 130_2p of the second semiconductor film 130_2. A portion of the second data storage film 132_2 may be disposed between the channel layer CHL and the second semiconductor film 130_2. A portion of the second data storage film 132_2 may be disposed between the third capping insulating layer 153 and the second semiconductor film 130_2. The second data storage film 132_2 may contain the same material as that of the first data storage film 132_1, but example embodiments are not limited thereto.

In some example embodiments, the second data storage film 132_2 may be formed of multiple films. For example, as shown in FIG. 5, the second data storage film 132_2 may include a second tunnel insulating film 132d, a second charge storage film 132e and a second blocking insulating film 132f, which are sequentially stacked on the outer side of the second semiconductor film 130_2.

The descriptions of the second tunnel insulating film 132d, the second charge storage film 132e and the second blocking insulating film 132f may be substantially the same as those of the first tunnel insulating film 132a, the first charge storage film 132b, and the first blocking insulating film 132c, respectively.

In some example embodiments, the second channel structure CH2 may further include a second filling insulating layer 134_2. The second filling insulating layer 134_2 may be formed to fill the inside of the second semiconductor film 130_2. The second filling insulating layer 134_2 may contain the same material as that of the first filling insulating layer 134_1, but example embodiments are not limited thereto.

In some example embodiments, the second channel structure CH2 may further include a second channel pad 136_2. The second channel pad 136_2 may be formed to be connected to a lower end of the second semiconductor film 130_2. The second channel pad 136_2 may be disposed on the second filling insulating layer 134_2. The second channel pad 136_2 may be in contact with the second filling insulating layer 134_2 and the second channel pad 136_2. The second channel pad 136_2 may contain the same material as that of the first channel pad 136_1, but example embodiments are not limited thereto.

The insertion insulating pattern ILP may be disposed between the second channel structure CH2 and another second channel structure CH2. The insertion insulating pattern ILP may be extended to the first capping insulating layer 151 by passing through the channel layer CHL. The insertion insulating pattern ILP may be formed to overlap or not to overlap the division pattern WC in the third direction Z. The insertion insulating pattern ILP may contain an insulating material, for example, silicon oxide, but example embodiments are not limited thereto.

The division pattern WC may be formed over the cell array area CA and the extension area EA. The division pattern WC may be extended lengthwise in the first direction X and dividing the stacked structures SS1 and SS2. Also, a plurality of division patterns WC may be respectively extended in the first direction X, and may be arranged along the second direction Y by being spaced apart from each other. The stacked structures SS1 and SS2 may be divided by the plurality of division patterns WC to form a plurality of memory cell blocks (e.g., BLK1 to BLKn of FIG. 1). For example, two adjacent division patterns WC may define one memory cell block therebetween. A plurality of channel structures CH may be disposed in each of memory cell blocks defined by the division patterns WC.

The division pattern WC may include a first portion WC1 and a second portion WC2. The first portion WC1 may be disposed on the first capping insulating layer 151. The second portion WC2 may be disposed on the first portion WC1. The first portion WC1 may contain an insulating material, for example, at least one of silicon oxide, silicon nitride and/or silicon oxynitride, but example embodiments are not limited thereto. The second portion WC2 may contain at least one of carbon, an insulating material, or Poly Si.

Based on an upper surface 151US of the first capping insulating layer 151, a height H2 of a lower surface WC2_BS of the second portion WC2 may be greater than a height H1 of an upper surface 136_1US of the first channel pad 136_1. That is, based on the upper surface 151US of the first capping insulating layer 151, a height H2 of an upper surface WC1_US of the first portion WC1 may be greater than the height H1 of the upper surface 136_1US of the first channel pad 136_1.

The gate contact 162 may be disposed in the extension area EA. A plurality of gate contacts 162 may be electrically connected to the plurality of corresponding gate electrodes 112 and 117. For example, each of the gate contacts 162 may be extended in the third direction Z to pass through the first interlayer insulating layer 141 and/or the second interlayer insulating layer 142, and may be connected to a corresponding one of the gate electrodes 112 and 117. In some example embodiments, a width of the gate contact 162 may be reduced toward the gate electrodes 112 and 117.

In some example embodiments, each of the gate contacts 162 may pass through the stacked structures SS1 and SS2. For example, a plurality of third contact pads 312 may be formed in the pad insulating layer 330 of the extension area EA. For example, the plurality of third contact pads 312 may be formed in the pad insulating layer 330 in the extension area EA. The plurality of gate contacts 162 may be electrically connected to their corresponding third contact pads 312 by passing through the stacked structures SS1 and SS2. In some example embodiments, each of the gate contacts 162 may include a first through portion 162a, a second through portion 162b, and a protrusion portion 162p.

The first through portion 162a may be extended in the third direction Z, and may be connected to the third contact pad 312 by passing through the first base insulating layer 102, the first stacked structure SS1 and the first interlayer insulating layer 141. The second through portion 162b may be connected to the first through portion 162a by passing through the second base insulating layer 104, the second stacked structure SS2 and the second interlayer insulating layer 142. The protrusion portion 162p may be protruded from a side of the first through portion 162a or a side of the second through portion 162b to contact at least one of the gate electrodes 112 and 117. In some example embodiments, the protrusion portion 162p may be in contact with a lowermost gate electrode (hereinafter, referred to as a selection gate electrode) disposed at the lowermost portion of each step of the gate electrodes 112 and 117 of the extension area EA.

Among the gate electrodes 112 and 117, the gate electrodes (hereinafter, referred to as non-selection gate electrodes) other than the selection gate electrode may be spaced apart from the gate contact 162. For example, a first insulating ring 160a may be formed between the non-selection gate electrodes and the first through portion 162a, and a second insulating ring 160b may be formed between the non-selection gate electrodes and the second through portion 162b. The first insulating ring 160a and the second insulating ring 160b may not be interposed between the gate contact 162 and the selection gate electrode.

In some example embodiments, the gate contact 162 may have a step difference between the first stacked structure SS1 and the second stacked structure SS2. For example, a width of the first through portion 162a may be reduced toward the third contact pad 312, and a width of the second through portion 162b may be reduced toward the first through portion 162a. Also, on a boundary surface between the first interlayer insulating layer 141 and the second base insulating layer 104, the width of the first through portion 162a may be greater than the width of the second through portion 162b.

In some example embodiments, the first through via 164 may have a step difference between the first stacked structure SS1 and the second stacked structure and SS2. For example, the first through via 164 may include a third through portion 164a and a fourth through portion 164b. The third through portion 164a may be connected to the first contact pad 314 by passing through the first interlayer insulating layer 141. The fourth through portion 164b may be connected to the third through portion 164a by passing through the second interlayer insulating layer 142. A width of the third through portion 164a may be reduced toward the first contact pad 314, and a width of the fourth through portion 164b may be reduced toward the third through portion 164a. Also, on a boundary surface between the first interlayer insulating layer 141 and the second interlayer insulating layer 142, the width of the third through portion 164a may be greater than the width of the fourth through portion 164b.

In some example embodiments, the second through via 166 may have a step difference between the first stacked structure SS1 and the second stacked structure and SS2. For example, the second through via 166 may include a fifth through portion 166a and a sixth through portion 166b. The fifth through portion 166a may be connected to the second contact pad 316 by passing through the first interlayer insulating layer 141. The sixth through portion 166b may be connected to the fifth through portion 166a by passing through the second interlayer insulating layer 142. A width of the fifth through portion 166a may be reduced toward the second contact pad 316, and a width of the sixth through portion 166b may be reduced toward the fifth through portion 166a. Also, on the boundary surface between the first interlayer insulating layer 141 and the second interlayer insulating layer 142, the width of the fifth through portion 166a may be greater than the width of the sixth through portion 166b.

The dam structure 168 may be disposed in the outer area PA. Although not shown, in some example embodiments, the dam structure 168 may be disposed in the extension area EA. When viewed in a plan view, the dam structure 168 may surround at least a portion of the stacked structures SS1 and SS2. The dam structure 168 may be extended in the third direction Z. The dam structure 168 may pass through the first interlayer insulating layer 141 and the second interlayer insulating layer 142. The first interlayer insulating layer 141 and the second interlayer insulating layer 142 may include a dam hole 186h extended in the third direction Z. The dam structure 168 may fill a portion of the dam hole 186h. The other portion of the dam hole 186h may be filled by an insulating pattern 167 that will be described later. The dam structure 168 may be connected to a dam contact pad 318 by passing through the first and second interlayer insulating layers 141 and 142.

The dam contact 168c may be connected to the dam structure 168. The dam structure 168 may be disposed on the dam contact 168c. The dam contact 168c may be connected to the dam structure 168 by passing through the first capping insulating layer 151, the second capping insulating layer 152 and the third capping insulating layer 153. The dam contact 168c may contain a conductive material, for example, at least one of aluminum (Al), copper (Cu), tungsten (W), molybdenum (Mo), cobalt (Co), ruthenium (Ru) or their alloy, but example embodiments are not limited thereto. For example, the dam contact 168c may contain tungsten.

In some example embodiments, the dam structure 168 and the dam contact 168c may be integral structures having no interface. The dam structure 168 and the dam contact 168c may be formed at the same level. A width of the dam contact 168c may be reduced toward the dam structure 168.

The dam structure 168 may be extended in the third direction Z by passing through upper surfaces of the first interlayer insulating layer 141 and the second interlayer insulating layer 142. The dam structure 168 may be disposed on an upper surface 168c_US of the dam contact 168c. A width of the dam structure 168 may be reduced toward the dam contact 168c. The dam structure 168 may contain a conductive material, for example, at least one of aluminum (Al), copper (Cu), tungsten (W), molybdenum (Mo), cobalt (Co), ruthenium (Ru) or their alloy, but example embodiments are not limited thereto. The dam structure 168 may contain the same material as that of the dam contact 168c. For example, the dam structure 168 may contain tungsten (W).

The insulating pattern 167 may be disposed between the first capping insulating layer 151 and the dam structure 168. The insulating pattern 167 may be disposed on a portion of a lower surface of the dam structure 168. The insulating pattern 167 may be disposed on the upper surface 151US of the first capping insulating layer 151. The insulating pattern 167 may surround a portion of a side 168c_SW of the dam contact 168c. The insulating pattern 167 may contain an insulating material, for example, at least one of silicon oxide, silicon nitride and/or silicon oxynitride, but example embodiments are not limited thereto. For example, the insulating pattern 167 may contain silicon oxide.

A width W1 of a lower surface 168BS of the dam structure 168 may be greater than a width W3 of the upper surface 168c_US of the dam contact 168c. The width W1 of the lower surface 168BS of the dam structure 168 may be equal to or substantially equal to a sum of the width W3 of the upper surface 168c_US of the dam contact 168c and a width W2 of an upper surface 167US of the insulating pattern 167.

In some example embodiments, a level of the lower surface 168BS of the dam structure 168 may be higher than a level of the upper surface 136_1US of the first channel pad 136_1. In other words, based on the upper surface of the first capping insulating layer 151, a height H3 of the lower surface 168BS of the dam structure 168 may be higher than a height H1 of the upper surface 136_1US of the first channel pad 136_1.

The lower contact 162c may be connected to the gate contact 162 by passing through the first capping insulating layer 151, the second capping insulating layer 152 and the third capping insulating layer 153. The lower contact 162c may contain a conductive material, for example, at least one of aluminum (Al), copper (Cu), tungsten (W), molybdenum (Mo), cobalt (Co), ruthenium (Ru) or their alloy, but example embodiments are not limited thereto.

The lower contact 162c may contain the same material as that of the gate contact 162. The lower contact 162c and the gate contact 162 may be integral structures having no interface.

The first via contact 164c may be connected to the first through via 164 by passing through the first capping insulating layer 151, the second capping insulating layer 152 and the third capping insulating layer 153. The second via contact 166c may be connected to the second through via 166 by passing through the first capping insulating layer 151, the second capping insulating layer 152 and the third capping insulating layer 153.

The first via contact 164c and the second via contact 166c may contain a conductive material, for example, at least one of aluminum (Al), copper (Cu), tungsten (W), molybdenum (Mo), cobalt (Co), ruthenium (Ru) or their alloy, but example embodiments are not limited thereto.

The first wiring structure 180 may be formed on the third capping insulating layer 153. The first wiring structure 180 may be electrically connected to the channel structure CH, the gate contact 162, the first through via 164, the second through via 166 and/or the dam structure 168. For example, a first inter-wiring insulating layer 144 may be disposed on the third capping insulating layer 153. The first wiring structure 180 may be formed in the first inter-wiring insulating layer 144 and thus connected to the channel structure CH, the gate contact 162, the first through via 164, the second through via 166 and/or the dam structure 168. The number and arrangement of layers of the first wiring structure 180 are only for example, and example embodiments are not limited to the shown example.

The first wiring structure 180 may contain a conductive material, for example, at least one of aluminum (Al), copper (Cu), tungsten (W), molybdenum (Mo), cobalt (Co), ruthenium (Ru) or their alloy, but example embodiments are not limited thereto. For example, the first wiring structure 180 may include a copper (Cu) wiring.

In some example embodiments, the first wiring structure 180 may include a conductive line 185 disposed in the cell array area CA. The conductive line 185 may be extended lengthwise in the second direction Y. Also, a plurality of conductive lines 185 may be extended in the second direction Y, and may be arranged along the first direction X by being spaced apart from each other.

The conductive line 185 may be electrically connected to the plurality of channel structures CH arranged along the second direction Y. For example, the conductive line 185 may be connected to the other end (e.g., a lower end) of the second semiconductor film 130_2 through the second channel pad 136_2 of the second channel structure CH2. The conductive line 185 may be provided as a bit line (e.g., BL of FIG. 2) of the semiconductor memory device according to some example embodiments.

The source layer 300 may be formed on an upper surface of the first stacked structure SS1. The source layer 300 of the cell array area CA may be electrically connected to the plurality of channel structures CH. For example, one end (e.g., an upper end) of the first semiconductor film 130_1 more protruded than the first stacked structure SS1 and the first data storage film 132_1 may be in contact with the source layer 300. The source layer 300 may be in contact with a portion of the division pattern WC. The source layer 300 may surround a portion of the division pattern WC.

The source layer 300 may contain a conductive material, for example, polysilicon doped with impurities, metal, or metal silicide, but example embodiments are not limited thereto. For example, the source layer 300 may contain poly-Si doped with N-type impurities (e.g., phosphorus (P), arsenic (As), etc.) The source layer 300 may be provided as a common source line (e.g., CSL of FIG. 2) of the semiconductor memory device according to some example embodiments.

The pad insulating layer 330 may be disposed on the first interlayer insulating layer 141. The pad insulating layer 330 may form an insulating area over the extension area EA and the outer area PA. The pad insulating layer 330 may contain at least one of, for example, silicon oxide, silicon oxynitride and/or a low dielectric constant (low-k) material having a dielectric constant lower than that of silicon oxide, but example embodiments are not limited thereto.

The first upper insulating layer 335 may be disposed on an upper surface of the pad insulating layer 330. The first upper insulating layer 335 may be in contact with the source layer 300. The first upper insulating layer 335 may contain at least one of, for example, silicon oxide, silicon oxynitride and/or a low dielectric constant (low-k) material having a dielectric constant lower than that of silicon oxide, but example embodiments are not limited thereto.

The second upper insulating layer 340 may be disposed on the source layer 300 and the first upper insulating layer 335. The second upper insulating layer 340 may contain at least one of, for example, silicon oxide, silicon oxynitride and/or a low dielectric constant (low-k) material having a dielectric constant lower than that of silicon oxide, but example embodiments are not limited thereto.

The connection pattern 380 may be disposed on an upper surface of the second upper insulating layer 340. The connection pattern 380 may electrically connect the first through via 164 with the source layer 300. For example, the first contact pad 314 connected to the first through via 164 may be formed in the pad insulating layer 330. Also, a first contact pattern 362 for connecting the source layer 300 with the connection pattern 380 by passing through the second upper insulating layer 340 may be formed, and a second contact pattern 364 for connecting the first contact pad 314 with the connection pattern 380 by passing through the first upper insulating layer 335 and the second upper insulating layer 340 may be formed.

The conductive pad 390 may be disposed on an upper surface of the second upper insulating layer 340. The conductive pad 390 may be electrically connected to the second through via 166. For example, the first contact pad 314 connected to the second through via 166 may be disposed in the pad insulating layer 330. Also, a third contact pattern 366 for connecting the second contact pad 316 with the conductive pad 390 by passing through the second upper insulating layer 340 may be disposed.

The peripheral circuit structure PERI may include a peripheral circuit board 200, a peripheral circuit element PT, and a second wiring structure 280.

The peripheral circuit board 200 may include, for example, a semiconductor substrate such as a silicon substrate, a germanium substrate, and a silicon-germanium substrate. Alternatively, the peripheral circuit board 200 may include a silicon-on-insulator (SOI) substrate or a germanium-on-insulator (GOI) substrate.

The peripheral circuit element PT may be formed on the peripheral circuit board 200. The peripheral circuit element PT may constitute a peripheral circuit (e.g., 30 of FIG. 1) that controls the operation of the semiconductor memory device. For example, the peripheral circuit element PT may include a control logic (e.g., 37 of FIG. 1), a row decoder (e.g., 33 of FIG. 1), and a page buffer (e.g., 35 of FIG. 1). In the following description, a surface of the peripheral circuit board 200, on which the peripheral circuit element PT is disposed, may be referred to as a front side of the peripheral circuit board 200. On the contrary, a surface of the peripheral circuit board 200, which is opposite to the front side of the peripheral circuit board 200, may be referred to as a back side of the peripheral circuit board 200.

The peripheral circuit element PT may include, for example, a transistor, but example embodiments are not limited thereto. For example, the peripheral circuit element PT may include various passive elements such as a capacitor, a register, and an inductor as well as various active elements such as a transistor.

The second wiring structure 280 may be formed on the peripheral circuit element PT. For example, a second inter-wiring insulating layer 244 may be formed on the entire surface of the peripheral circuit board 200. The second wiring structure 280 may be formed in the second inter-wiring insulating layer 244 and thus electrically connected to the peripheral circuit element PT. The number and arrangement of layers of the second wiring structure 280 are shown as an example, and example embodiments are not limited to the shown example.

In some example embodiments, the memory cell structure CELL may be stacked on the peripheral circuit structure PERI. For example, the memory cell structure CELL may be stacked on an upper surface of the second inter-wire insulating layer 244.

In some example embodiments, the first surface 102a of the first base insulating layer 102 may face the peripheral circuit structure PERI. For example, the stacked structures SS1 and SS2 may be interposed between the source layer 300 and the peripheral circuit structure PERI and/or between the first base insulating layer 102 and the peripheral circuit structure PERI.

The semiconductor memory device according to some example embodiments may have a chip to chip (C2C) structure. The C2C structure means that an upper chip including the memory cell structure CELL is manufactured on a first wafer, a lower chip including the peripheral circuit structure PERI is manufactured on a second wafer different from the first wafer, and then the upper chip and the lower chip are connected to each other by a bonding method.

For example, the bonding method may mean a method for electrically connecting a first bonding metal 190 (and/or a first bonding insulating film 146) formed on the uppermost metal layer of the upper chip with a second bonding metal 290 (and/or a second bonding insulating layer 246) formed on the uppermost metal layer of the lower chip. For example, when the first bonding metal 190 and the second bonding metal 290 are formed of copper (Cu), the bonding method may be a Cu—Cu bonding method. However, this is only for example, and the first bonding metal 190 and the second bonding metal 290 may be formed of various other metals such as aluminum (Al) or tungsten (W), and example embodiments are not limited thereto.

As the first bonding metal 190 and the second bonding metal 290 are bonded to each other, the first wiring structure 180 may be electrically connected to the second wiring structure 280. Therefore, the plurality of memory cells formed in the cell array area CA may be electrically connected to the peripheral circuit element PT.

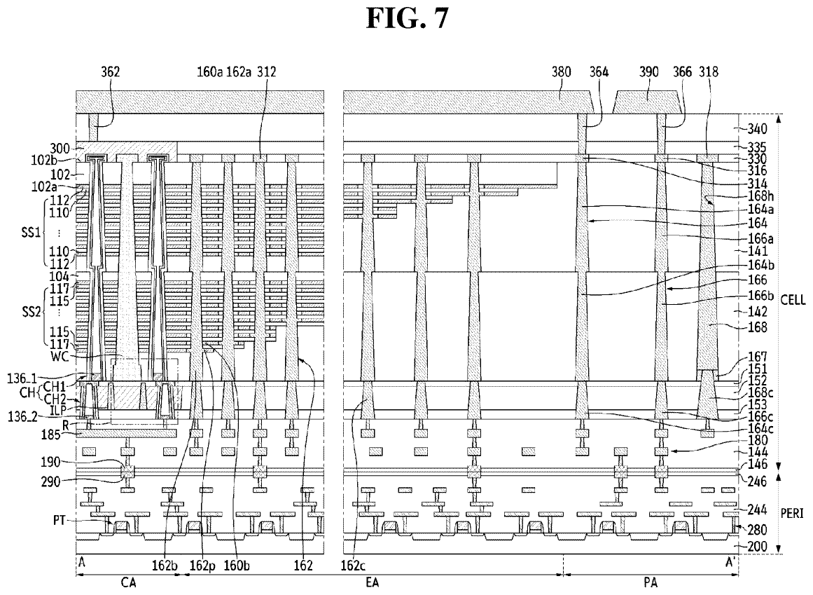

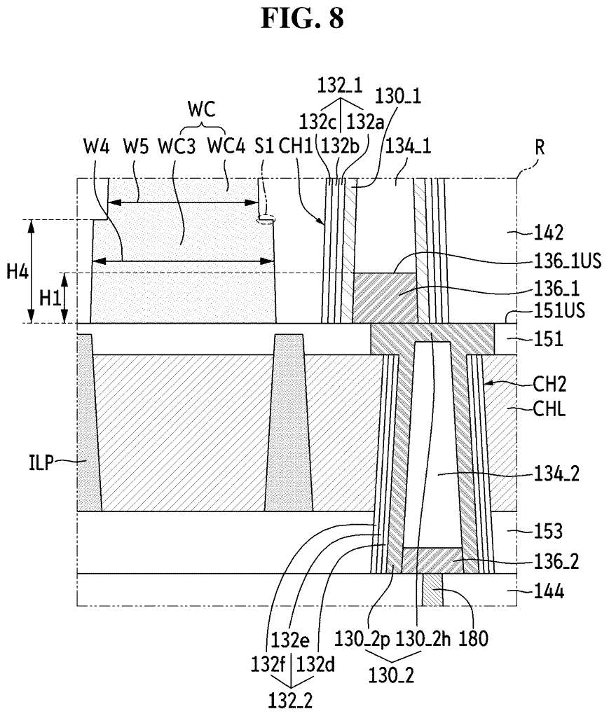

FIG. 7 is a view illustrating a semiconductor memory device according to some example embodiments of the present disclosure. FIG. 8 is an enlarged view illustrating a region R of FIG. 7. For convenience of description, redundant portions of those described with reference to FIGS. 4 to 6 will be briefly described or omitted.

Referring to FIGS. 7 and 8, the division pattern WC may include a third portion WC3 and a fourth portion WC4.

The division pattern WC may pass through portions of the first interlayer insulating layer 141, the second interlayer insulating layer 142 and the source layer 300 on the first capping insulating layer 151. The fourth portion WC4 of the division pattern WC may be disposed on the third portion WC3.

The third portion WC3 of the division pattern WC may have a fourth width W4. The fourth portion WC4 of the division pattern WC may have a fifth width W5. The fourth width W4 may be greater than the fifth width W5. The fourth width W4 may become narrower as the third portion WC3 becomes far away from the upper surface 151US of the first capping insulating layer 151. The fifth width W5 may become narrower as the fourth portion WC4 becomes far away from the upper surface 151US of the first capping insulating layer 151. The division pattern WC may have a step difference S1 at the boundary between the third portion WC3 and the fourth portion WC4. That is, the width of the division pattern WC may be discontinuously narrowed at the boundary between the third portion WC3 and the fourth portion WC4. That is, at the boundary between the third portion WC3 and the fourth portion WC4, the width of the third portion WC3 may be greater than the width of the fourth portion WC4.

A height H4 of the third portion WC3 may be greater than the height H1 of the first channel pad 136_1 based on the upper surface 151US of the first capping insulating layer 151.

The third portion WC3 and the fourth portion WC4 of the division pattern WC may contain the same material. The third portion WC3 and the fourth portion WC4 may contain an insulating material, for example, at least one of silicon oxide, silicon nitride and/or silicon oxynitride, but example embodiments are not limited thereto.

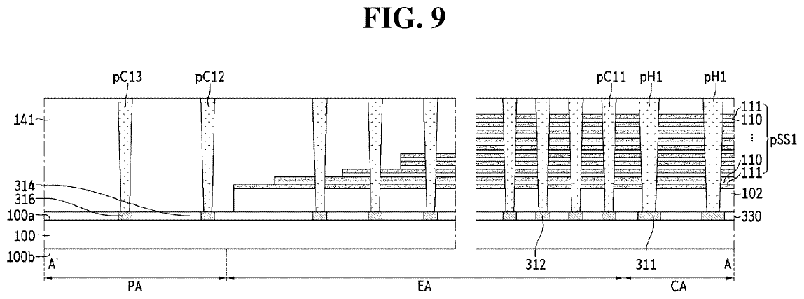

FIGS. 9 to 21 are views illustrating intermediate steps to describe a method for fabricating a semiconductor memory device according to some example embodiments. For convenience of description, redundant portions of those described with reference to FIGS. 4 to 8 will be briefly described or omitted.

Referring to FIG. 9, a pad insulating layer 330, a first contact pad 314, a second contact pad 316, a third contact pad 312, a sacrificial pad 311, a first base insulating layer 102, a first preliminary stack pSS1, a first preliminary channel pH1, a first preliminary gate contact pC11, a first preliminary through via pC12, and a second preliminary through via pC13 are formed on a base substrate 100.

The base substrate 100 may include, for example, a semiconductor substrate such as a silicon substrate, a germanium substrate, and a silicon-germanium substrate. Alternatively, the base substrate 100 may include a silicon-on-insulator (SOI) substrate or a germanium-on-insulator (GOI) substrate. However, example embodiments are not limited thereto.

The base substrate 100 may include a fifth surface 100a and a sixth surface 100b, which are opposite to each other. In the following description, the fifth surface 100a may be referred to as a front side of the base substrate 100, and the sixth surface 100b may be referred to as a back side of the base substrate 100.

The pad insulating layer 330 may be formed on the fifth surface 100a of the base substrate 100. The first contact pad 314, the second contact pad 316, the third contact pad 312 and the sacrificial pad 311 may be formed in the pad insulating layer 310. The first base insulating layer 102 and the first preliminary stack pSS1 may be sequentially stacked on the upper surface of the pad insulating layer 330. A first interlayer insulating layer 141 may cover the pad insulating layer 330, the first base insulating layer 102 and the first preliminary stack pSS1.

The first base insulating layer 102 and the first preliminary stack pSS1 may be sequentially stacked on the upper surface of the pad insulating layer 330. The first preliminary stack pSS1 may include a plurality of first mold insulating layers 110 and a plurality of first mold sacrificial layers 111, which are alternately stacked on the upper surface of the pad insulating layer 330. The first mold sacrificial layers 111 may contain a material having etch selectivity with respect to the first mold insulating layers 110. For example, each of the first mold insulating layers 110 may include a silicon oxide layer, and each of the first mold sacrificial layers 111 may include a silicon nitride layer. However, example embodiments are not limited thereto.

The first preliminary channel pH1 and the first preliminary gate contact pC11 may pass through the first preliminary stack pSS1. The first preliminary channel pH1 may be connected to the sacrificial pad 311. The first preliminary gate contact pC11 may be connected to the third contact pad 312. The first preliminary through via pC12 and the second preliminary through via pC13 may be connected to the first contact pad 314 and the second contact pad 316, respectively.

For example, the first interlayer insulating layer 141 covering the first base insulating layer 102 and the first preliminary stack pSS1 may be formed on the pad insulating layer 330. The first preliminary channel pH1 may be connected to the sacrificial pad 311 by passing through the first interlayer insulating layer 141, the first preliminary stack pSS1 and the first base insulating layer 102. The first preliminary gate contact pC11 may be connected to the third contact pad 312 by passing through the first interlayer insulating layer 141, the first preliminary stack pSS1 and the first base insulating layer 102. The first preliminary through via pC12 and the second preliminary through via pC13 may be connected to the first contact pad 314 and the second contact pad 316, respectively, by passing through the first interlayer insulating layer 141.

In some example embodiments, the first preliminary channel pH1, the first preliminary gate contact pC11, the first preliminary through via pC12 and the second preliminary through via pC13 may contain carbon. However, example embodiments are not limited thereto.

Referring to FIG. 10, a second base insulating layer 104, a second preliminary stack pSS2, a second preliminary channel pH2, a second preliminary gate contact pC21, a third preliminary through via pC22 and a fourth preliminary through via pC23 are formed on the first interlayer insulating layer 141.

The second base insulating layer 104 and the second preliminary stack pSS2 may be sequentially stacked on the first interlayer insulating layer 141. A second interlayer insulating layer 142 may cover the second base insulating layer 104 and the second preliminary stack pSS2.

The second preliminary channel pH2, the second preliminary gate contact pC21, the third preliminary through via pC22 and the fourth preliminary through via pC23 may pass through the second base insulating layer 104, the second preliminary stack pSS2 and the second interlayer insulating layer 142, respectively. The second preliminary channel pH2 may be connected to the first preliminary channel pH1. The second preliminary gate contact pC21 may be connected to the first preliminary gate contact pC11. The third preliminary through via pC22 may be connected to the first preliminary through via pC12. The fourth preliminary through via pC23 may be connected to the second preliminary through via pC13.

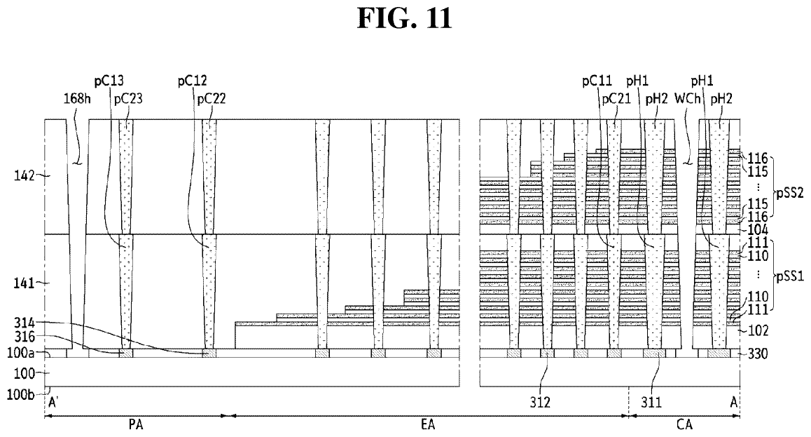

Referring to FIG. 11, a division area WCh and a dam hole 186h are formed.

The division area WCh may be extended in the first direction X, dividing the first preliminary stack pSS1 and the second preliminary stack pSS2. A lower surface of the division area WCh may be formed to be lower than the fifth surface 100a of the base substrate 100.

The dam hole 186h may be formed in the outer area PA. The dam hole 186h may surround the cell array area CA and the extension area EA in the outer area PA. A lower surface of the dam hole 186h may be formed to be lower than the fifth surface 100a of the base substrate 100.

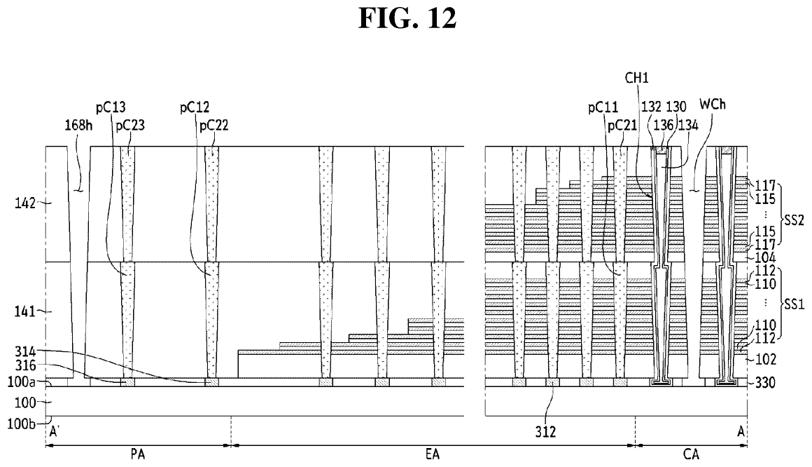

Referring to FIG. 12, a first channel structure CH1 and a plurality of gate electrodes 112 and 117 are formed.

For example, the first preliminary channel pH1 and the second preliminary channel pH2 may be selectively removed. Next, a first data storage film 132_1, a first semiconductor film 130_1, a first filling insulating layer 134_1 and a first channel pad 136_1 may be sequentially formed in the area from which the first preliminary channel pH1 and the second preliminary channel pH2 are removed. Therefore, a first channel structure CH1 connected to the base substrate 100 by passing through the first preliminary stack pSS1 and the second preliminary stack pSS2 may be formed.

For example, the mold sacrificial layers 111 and 116 exposed by the division area WCh may be selectively removed. Subsequently, the gate electrodes 112 and 117 replacing the area from which the mold sacrificial layers 111 and 116 are removed may be formed. As a result, the stacked structures SS1 and SS2 including the mold insulating layers 110 and 115 and the gate electrodes 112 and 117 may be formed.

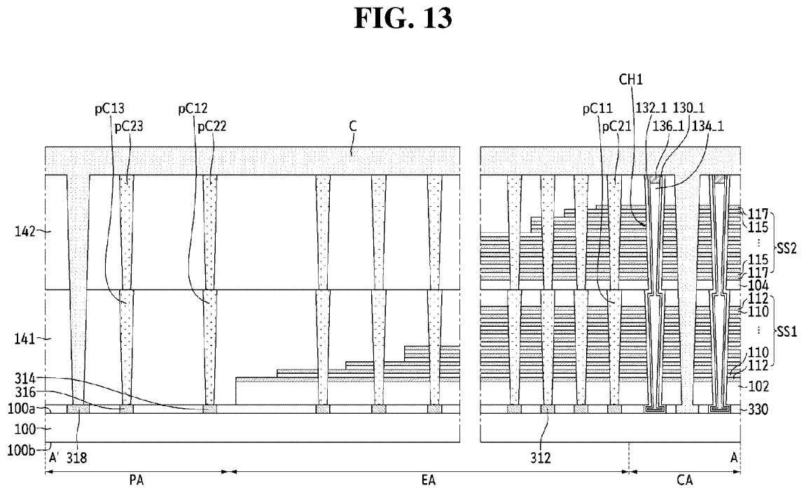

Referring to FIG. 13, the dam hole 186h and the division area WCh are filled with carbon (C).

A dam contact pad 318 may be formed in the dam hole 186h. Subsequently, the dam hole 186h and the division area WCh may be filled with carbon (C). In some example embodiments, after the dam hole 186h and the division area WCh are filled with carbon (c), a chemical mechanical polishing (CMP) process may be performed.

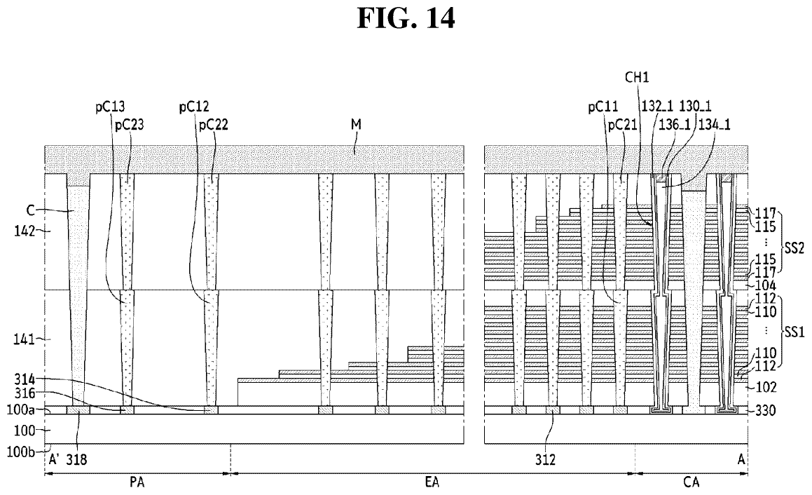

Referring to FIG. 14, an insulating material M is formed on the second interlayer insulating layer 142, the dam hole 186h and the division area WCh.

A portion of the carbon (C) filled in the dam hole 186h and the division area WCh may be removed by an etch back process. The etch back process may be performed until the carbon (C) filled in the division area WCh and the dam hole 186h becomes lower than a lower surface of the first channel pad 136_1. The division area WCh and the dam hole 186h may be filled with carbon (C) as the sacrificial layer. However, when a carbon (C) residue remains on the second interlayer insulating layer 142, there may be a difficulty in forming the second channel structure CH2 later. However, in the method for fabricating a semiconductor memory device according to some example embodiments of the present disclosure, the etch back process may be performed so that the carbon (C) filled in the division area WCh and the dam hole 186h becomes lower than the lower surface of the first channel pad 136_1, thereby reducing and/or preventing carbon residue contamination, which may improve the performance and/or reliability of the semiconductor device. In this case, the second channel structure CH may be actively formed on the first channel structure CH1 as a subsequent process.

Subsequently, the insulating material M may be filled in a portion of the division area WCh from which carbon (C) has been removed. The insulating material M may be filled in a portion of the dam hole 186h from which carbon (C) has been removed. The insulating material M may be formed on the second interlayer insulating layer 142. The insulating material M may include at least one of, for example, silicon oxide, silicon nitride and/or silicon oxynitride, but example embodiments are not limited thereto.

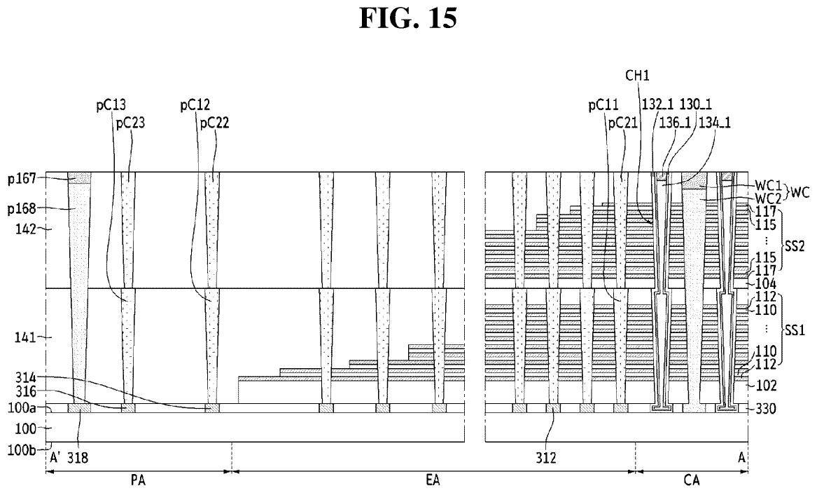

Referring to FIG. 15, a preliminary dam structure p168, a preliminary insulating pattern p167 and a division pattern WC are formed.

A portion of the insulating material M may be removed by the CMP process. The CMP process may be performed to reach an upper surface of the second interlayer insulating layer 142 so that the insulating material M may be removed. A portion of the insulating material M may be removed to form the division pattern WC including the first portion WC1 and the second portion WC2, the preliminary dam structure p168 and the preliminary insulating pattern p167.

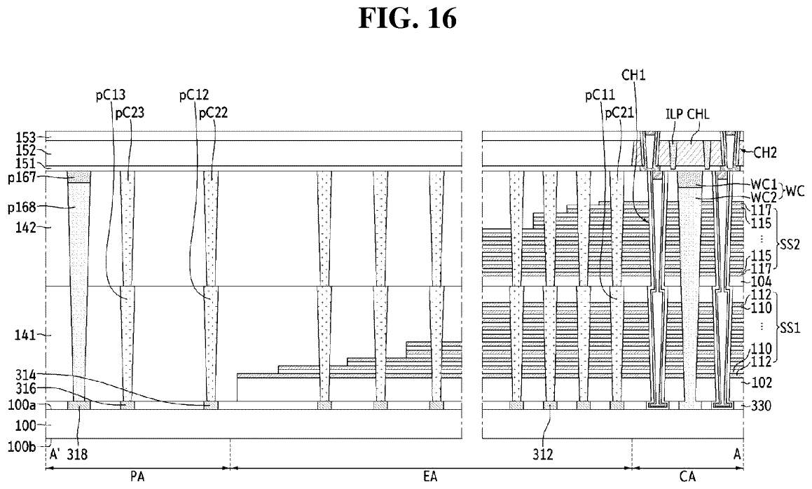

Referring to FIG. 16, the second channel structure CH2 and an insertion insulating pattern ILP are formed.

A first capping insulating layer 151, a second capping insulating layer 152 and a third capping insulating layer 153 may be sequentially formed on the second interlayer insulating layer 142. A channel layer CHL may be formed at the same level as the second capping insulating layer 152. That is, the channel layer CHL may be formed on the first capping insulating layer 151.

The second channel structure CH2 may be formed by passing through the first capping insulating layer 151, the channel layer CHL and the third capping insulating layer 153. The second channel structure CH2 may be formed on the first channel structure CH1. The second channel structure CH2 may be formed to partially overlap the first channel structure CH1 in the third direction Z.

The insertion insulating pattern ILP may be formed between the second channel structures CH2. The insertion insulating pattern ILP may pass through the channel layer CHL and the first capping insulating layer 151. The third capping insulating layer 153 may cover the insertion insulating pattern ILP.

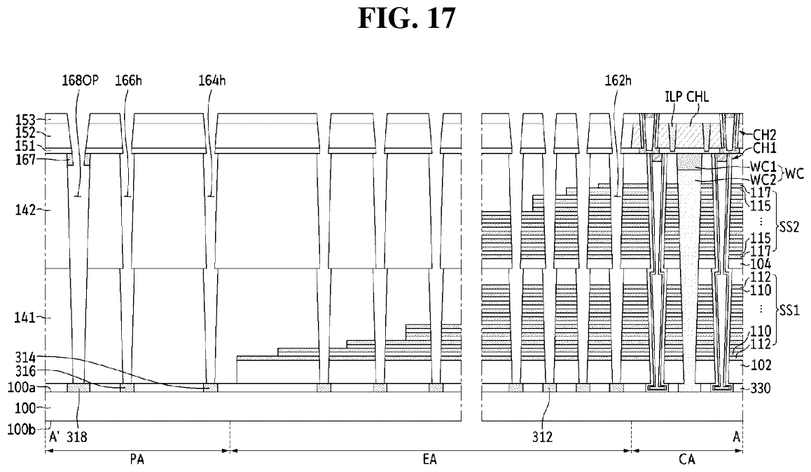

Referring to FIG. 17, a gate contact hole 162h, a first via hole 164h, a second via hole 166h and a dam structure open area 168OP are formed.

A hole may be formed in the first to third capping insulating layers 151, 152 and 153 by using an etching process. The hole may be formed in the first to third capping insulating layers 151, 152 and 153 to expose the second preliminary gate contact pC21, the third preliminary through via pC22, the fourth preliminary through via pC23, the preliminary insulating pattern p167 and the preliminary dam structure p168. A portion of the preliminary insulating pattern p167 may be removed by the etching process.

Subsequently, the carbon filled in the second preliminary gate contact pC21, the third preliminary through via pC22, the fourth preliminary through via pC23 and the preliminary dam structure p168 may be removed. When the carbon is removed, the gate contact hole 162h, the first via hole 164h, the second via hole 166h and the dam structure open area 168OP may be formed.

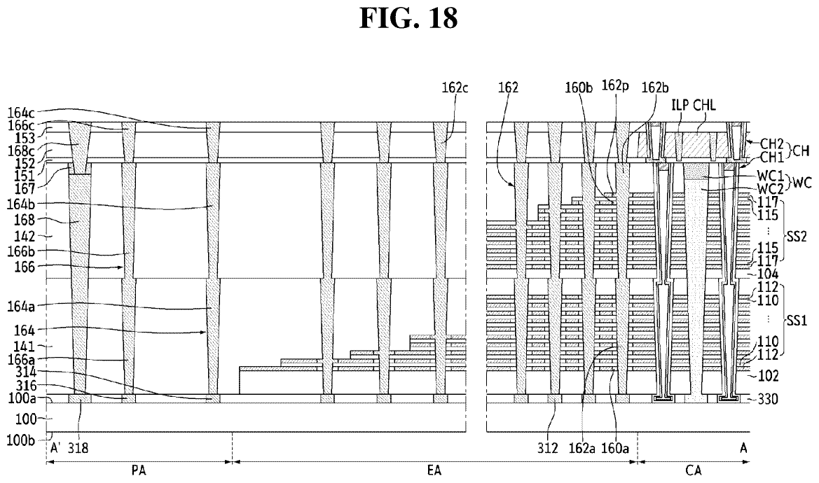

Referring to FIG. 18, a gate contact 162, a lower contact 162c, a first through via 164, a first via contact 164c, a second through via 166, a second via contact 166c, a dam structure 168, an insulating pattern 167 and a dam contact 168c are formed.

The gate contact hole 162h, the first via hole 164h, the second via hole 166h and the dam structure open area 168OP may be filled with a conductive material. The conductive material may contain, for example, metal such as tungsten (W), molybdenum (Mo), ruthenium (Ru), cobalt (Co) and nickel (Ni) or a semiconductor material such as silicon, but example embodiments are not limited thereto.

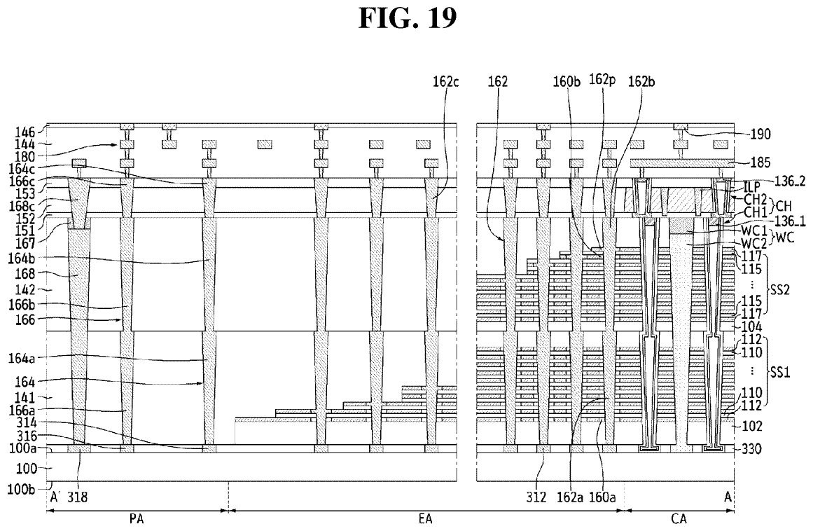

Referring to FIG. 19, a first inter-wiring insulating layer 144, a first wiring structure 180, a first bonding insulating film 146 and a first bonding metal 190 are formed.

The first inter-wiring insulating layer 144 and the first wiring structure 180 may be formed on the second interlayer insulating layer 142. The first wiring structure 180 may be electrically connected to the second channel structure CH2, the gate contact 162, the first through via 164, the second through via 166 and/or the dam contact 168c.

The first bonding insulating film 146 and the first bonding metal 190 may be formed on the first inter-wiring insulating layer 144. The first bonding metal 190 may be electrically connected to the first wiring structure 180.

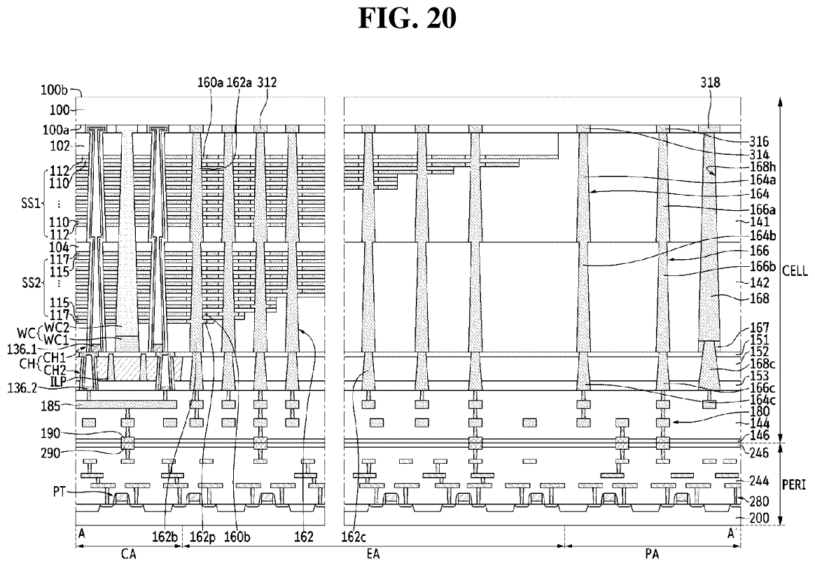

Referring to FIG. 20, a memory cell structure CELL is stacked on a peripheral circuit structure PERI.

In some example embodiments, the memory cell structure CELL may be stacked such that the fifth surface 100a of the base substrate 100 faces the peripheral circuit structure PERI. For example, the first bonding metal 190 (and/or the first bonding insulating film 146) formed on the uppermost metal layer of the memory cell structure CELL and a second bonding metal 290 (and/or a second bonding insulating layer 246) formed on the uppermost metal layer of the peripheral circuit structure PERI may be bonded to each other.

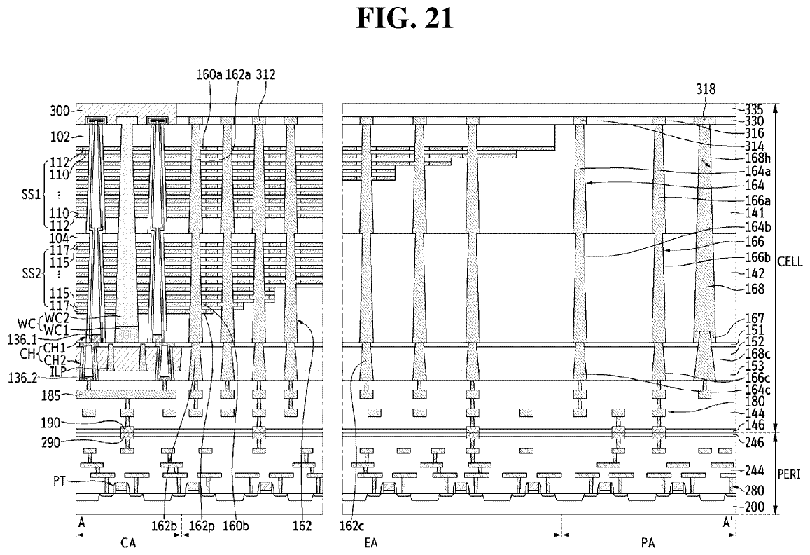

Referring to FIG. 21, a source layer 300 and a first upper insulating layer 335 are formed.

At least a portion of the base substrate 100 may be removed. For example, a planarization process and/or a recess process may be performed for the sixth surface 100b of the base substrate 100.

Subsequently, the first upper insulating layer 335 may be formed on the pad insulating layer 330.

The first upper insulating layer 335 may cover the pad insulating layer 330 over the cell array area CA, the extension area EA, and the outer area PA.

Subsequently, an etching process may be performed for the pad insulating layer 330 and the first upper insulating layer 335 of the cell array area CA. As the etching process is performed, an opening may be formed in the pad insulating layer 330 and the first upper insulating layer 335 of the cell array area CA. The channel structure CH, the division pattern WC and the first base insulating layer 102 of the cell array area CA may be exposed by the opening.

Subsequently, an upper portion of the first data storage film 132_1 may be removed. For example, the etching process may be performed for the first data storage film 132_1 exposed by the opening. As a result, one end (e.g., an upper end) of the first semiconductor film 130_1 may be exposed.

Subsequently, the source layer 300 may be formed on the first base insulating layer 102. The source layer 300 may cover the exposed first semiconductor film 130_1 and division pattern WC. The source layer 300 may contain a conductive material, for example, polysilicon doped with impurities, metal, or metal silicide, but example embodiments are not limited thereto. For example, the source layer 300 may contain poly-Si doped with N-type impurities (e.g., phosphorus (P) or arsenic (As)). Next, as shown in FIG. 4, a second upper insulating layer 340, a connection pattern 380, a conductive pad 390 and first to third contact patterns 362, 364 and 366 may be formed.

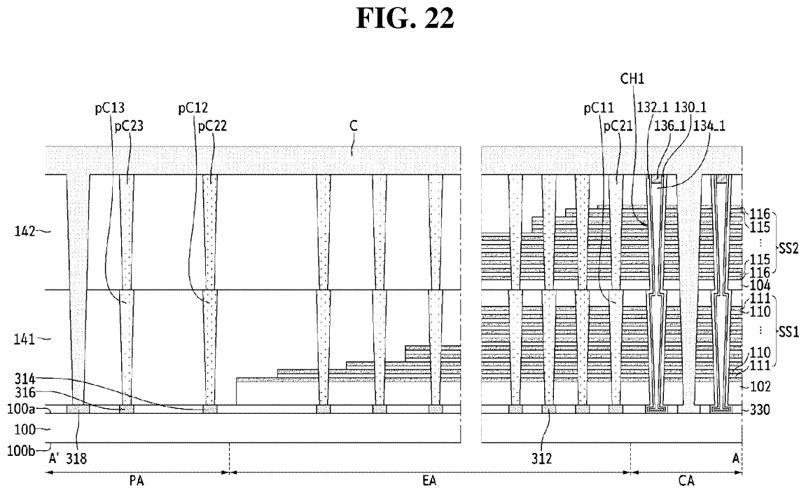

FIGS. 22 to 25 are views illustrating intermediate steps to describe a method for fabricating a semiconductor memory device according to some example embodiments. For convenience of description, redundant portions of those described with reference to FIGS. 9 to 21 will be briefly described or omitted. FIG. 22 is a view illustrating a process for next steps of FIG. 11.

Referring to FIG. 22, a first channel structure CH1 is formed, and carbon (C) is filled in the dam hole 186h and the division area WCh.

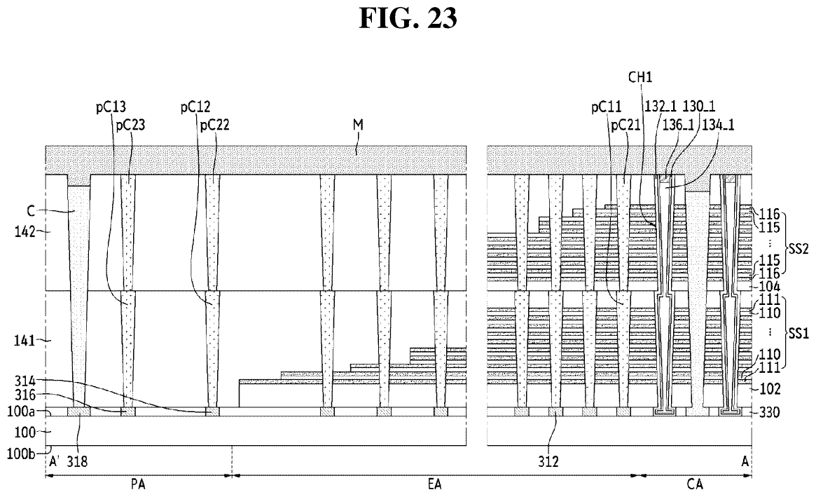

Referring to FIG. 23, a portion of the carbon (C) filled in the dam hole 186h and the division area WCh is removed, and an insulating material M is formed on the second interlayer insulating layer 142, the dam hole 186h and the division area WCh.

A portion of the carbon filled in the dam hole 186h and the division area WCh may be removed by performing an etch back process. The etch back process may be performed until the carbon (C) filled in the division area WCh and the dam hole 186h becomes lower than the lower surface of the first channel pad 136_1. Subsequently, a portion of the division area WCh from which carbon has been removed may be filled with the insulating material M. The insulating material M may be filled in a portion of the dam hole 186h from which the carbon (C) has been removed. The insulating material M may be formed on the second interlayer insulating layer 142.

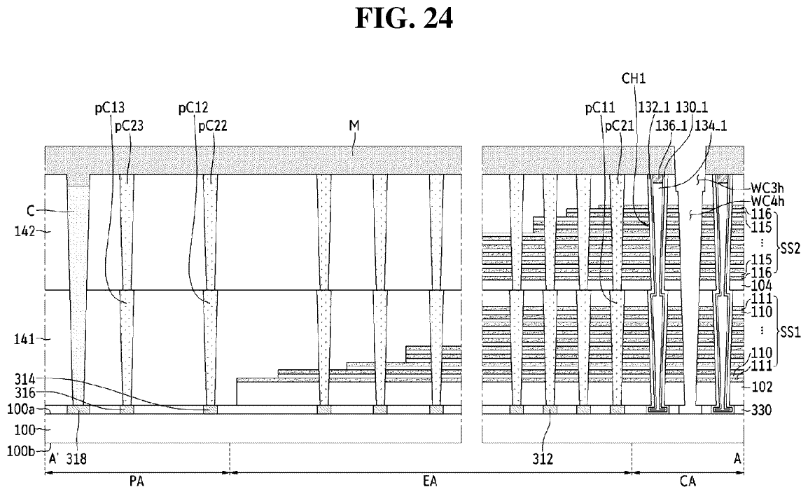

Referring to FIG. 24, the division area WCh is opened to form a first open area WC3h and a second open area WC4h.

The insulating material M may be removed so that the open area may be formed on the division area WCh. The carbon filled in the division area WCh exposed by the open areas WC3h and WC4h may be removed. When the carbon is removed, the first open area WC3h and the second open area WC4h may be formed. A width of the first open area WC3h may be greater than a width of the second open area WC4h.

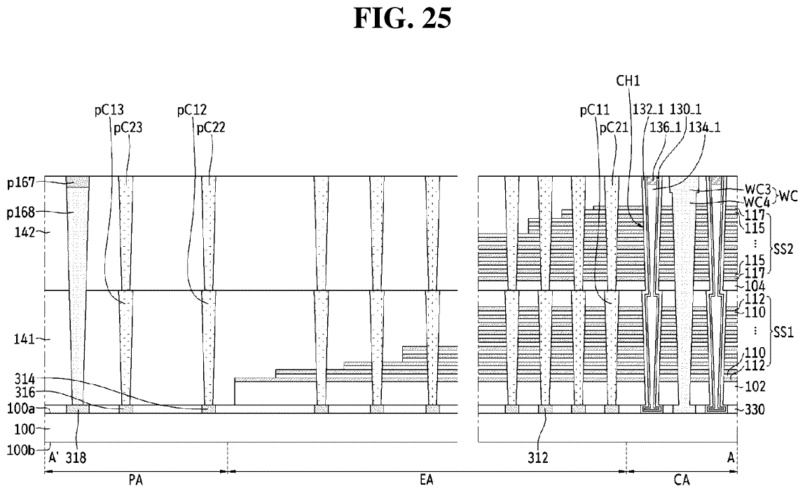

Referring to FIG. 25, a plurality of gate electrodes 112 and 117, a division pattern WC, a preliminary insulating pattern p167 and a preliminary dam structure p168 are formed.

For example, the mold sacrificial layers 111 and 116 exposed by the division area WCh may be selectively removed. Subsequently, the gate electrodes 112 and 117 replacing the area from which the mold sacrificial layers 111 and 116 are removed may be formed. As a result, the stacked structures SS1 and SS2 including the mold insulating layers 110 and 115 and the gate electrodes 112 and 117 may be formed.

Subsequently, the insulating material may be filled in the first open area WC3h and the second open area WC4h. Then, the CMP process may be performed up to the upper surface of the second interlayer insulating layer 142.

A subsequent process may be the same as shown in FIGS. 16 to 21.

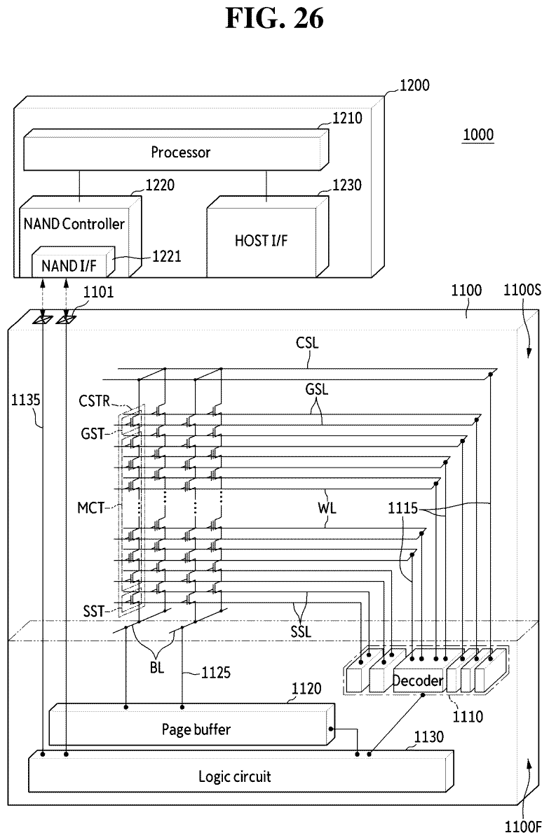

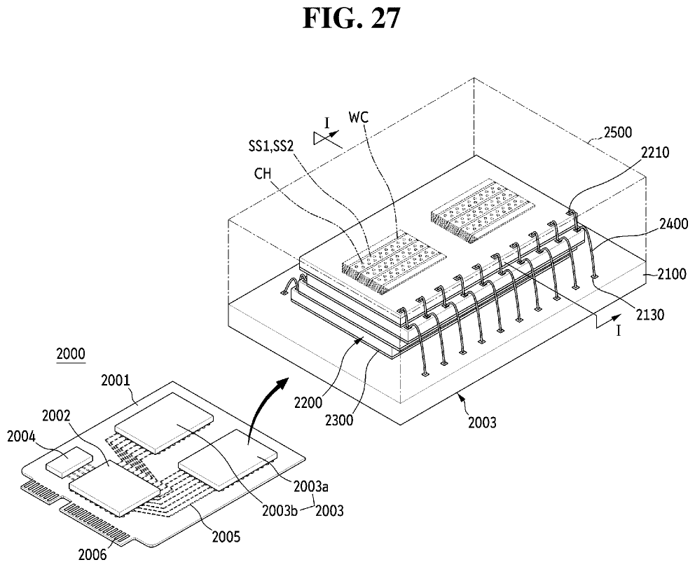

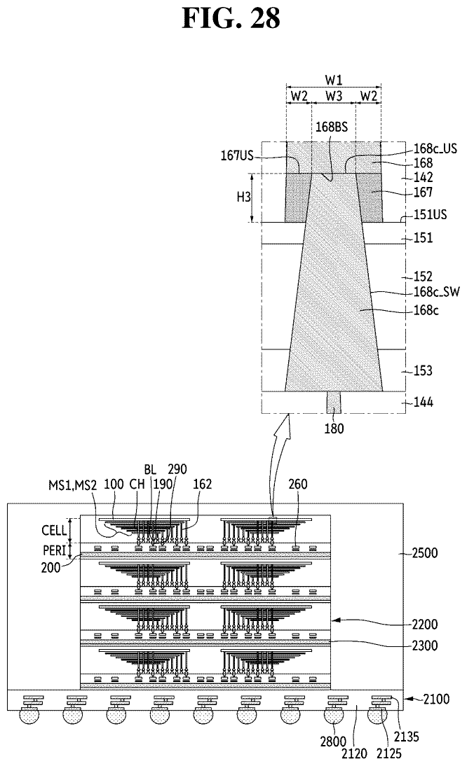

FIG. 26 is an example block diagram illustrating an electronic system according to some example embodiments of the present disclosure. FIG. 27 is an example perspective view illustrating an electronic system according to some example embodiments of the present disclosure. FIG. 28 is a schematic cross-sectional view taken along line I-I of FIG. 27. For convenience of description, redundant portions of those described with reference to FIGS. 1 to 25 will be briefly described or omitted.

Referring to FIG. 26, an electronic system 1000 according to some example embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive (SSD) device, a universal serial bus (USB), a computing system, a medical device, or a communication device, which includes one or more semiconductor memory devices 1100.

The semiconductor memory device 1100 may be a non-volatile memory device (e.g., NAND flash memory device), and include, for example, at least one of the semiconductor memory devices described with reference to FIGS. 1 to 8. The semiconductor memory device 1100 may include a first structure 1100F and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1) and a logic circuit 1130 (e.g., the control logic 37 of FIG. 1). For example, the first structure 1100F may correspond to the peripheral circuit structure PERI described above with reference to FIGS. 1 to 8.

The second structure 1100S may include a common source line CSL, a plurality of bit lines BL and a plurality of cell strings CSTR, which are described above with reference to FIG. 2. The cell strings CSTR may be connected to the decoder circuit 1110 through a plurality of word line WL, at least one string selection line SSL and at least one ground selection line GSL. In addition, the cell strings CSTR may be connected to the page buffer 1120 through the bit lines BL. For example, the second structure 1100S may correspond to the cell structure CELL described above with reference to FIGS. 1 to 8.

In some example embodiments, the bit lines BL may be electrically connected to the page buffer 1120 through second connection lines 1125.

The semiconductor memory device 1100 may perform communication with the controller 1200 through an input/output pad 1101 electrically connected to the logic circuit 1130 (e.g., the control logic 37 of FIG. 1). For example, the input/output pad 1101 may correspond to the conductive pad 390 described with reference to FIGS. 1 to 8. The input/output pad 1101 may be electrically connected to the logic circuit 1130 through an input/output connection line 1135 extended from the first structure 1100F to the second structure 1100S. The input/output connection line 1135 may correspond to the through via 166 described above with reference to FIGS. 1 to 8.

The controller 1200 may include a processor 1210, a NAND controller 1220 and a host interface 1230. In some example embodiments, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate in accordance with desired (and/or alternatively predetermined) firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 27 and 28, an electronic system according to some example embodiments may include a main board 2001, a main controller 2002 packaged on the main board 2001, one or more semiconductor packages 2003 and a DRAM 2004. The semiconductor package 2003 and the DRAM 2004 may be connected to the main controller 2002 by wiring patterns 2005 formed in the main board 2001. The main board 2001 may include a connector 2006 that includes a plurality of pins coupled to the external host. The number and arrangement of the plurality of pins in the connector 2006 may be varied depending on a communication interface between the electronic system 2000 and the external host. In some example embodiments, the electronic system 2000 may perform communication with the external host in accordance with any one of interfaces such as a Universal Serial Bus (USB), a Peripheral Component Interconnect Express (PCI-Express), Serial Advanced Technology Attachment (SATA) and M-Phy for Universal Flash Storage (UFS). In some example embodiments, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003.

The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003, which is a data storage space, and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210.

The input/output pad 2210 may correspond to the input/output pad 1101 of FIG. 26.

In some example embodiments, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connection structure that includes a through silicon via TSV, instead of the connection structure 2400 of the bonding wire manner.

In some example embodiments, the main controller 2002 and the semiconductor chips 2200 may be included in one package. In some example embodiments, the main controller 2002 and the semiconductor chips 2200 may be packaged on a separate interposer substrate different from the main board 2001, and the main controller 2002 may be connected with the semiconductor chips 2200 by a wire formed in the interposer substrate.

In some example embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 with the lower pads 2125 inside the package substrate body portion 2120. The package upper pads 2130 may be electrically connected to the connection structures 2400. The lower pads 2125 may be connected to the wiring patterns 2005 of the main board 2001 of the electronic system 2000 through conductive connectors 2800 as shown in FIG. 27.

In the electronic system 2000 according to some example embodiments, each of the semiconductor chips 2200 may include the semiconductor memory device described with reference to FIGS. 1 to 8. For example, each of the semiconductor chips 2200 may include a memory cell structure CELL and a peripheral circuit structure PERI. Illustratively, the memory cell structure CELL may include the first stacked structure SS1, the second stacked structure SS2, the channel structure CH, the division pattern WC, the first through via 164, the second through via 166, the dam structure 168, the first wiring structure 180 and the source layer 300, which are described with reference to FIGS. 1 to 8. The peripheral circuit structure PERI may include the peripheral circuit board 200 and the second wiring structure 280. The memory cell structure CELL and the peripheral circuit structure PERI may be bonded to each other through the first bonding metal 190 and the second bonding metal 290.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor memory device comprising:
a substrate;
a stacked structure including a plurality of gate electrodes stacked on the substrate and spaced apart from each other in a first direction, the first direction being perpendicular to an upper surface of the substrate;
a channel structure extending in the first direction and crossing the plurality of gate electrodes; and
a dam structure extending in the first direction and surrounding at least a portion of the stacked structure in a plan view, on the substrate,
wherein a height of an upper surface of the dam structure from the upper surface of the substrate is lower than a height of the channel structure from the upper surface of the substrate.

2. The semiconductor memory device of claim 1, further comprising
an interlayer insulating layer surrounding the stacked structure, the channel structure, and the dam structure,
a capping insulating layer on the interlayer insulating layer, the channel structure, the stacked structure, and the dam structure, and
an insulating pattern between the capping insulating layer and the dam structure.

3. The semiconductor memory device of claim 2, further comprising
a dam contact connected to the dam structure, and
the dam contact passing through the capping insulating layer and the insulating pattern.

4. The semiconductor memory device of claim 3, wherein a width of the upper surface of the dam structure is greater than a width of a lower surface of the dam contact.

5. The semiconductor memory device of claim 3, wherein a width of the upper surface of the dam structure is a same width as a sum of a width of a lower surface of the dam contact and a width of a lower surface of the insulating pattern.

6. The semiconductor memory device of claim 2, wherein the channel structure includes
a first channel structure crossing the plurality of gate electrodes, and
a second channel structure connected to the first channel structure, the second channel structure passing through the capping insulating layer.

7. The semiconductor memory device of claim 6, further comprising an insertion insulating pattern between the second channel structure and another second channel structure.

8. The semiconductor memory device of claim 1, further comprising a division pattern extending in a second direction through the stacked structure, the second direction crossing the first direction,
wherein the division pattern includes
a first portion containing a first material,
a second portion on the first portion,
the second portion containing a second material,
the first material containing an insulating material, and
the second material containing at least one of an insulating material including carbon or silicon.

9. The semiconductor memory device of claim 8, wherein the channel structure includes
a semiconductor film crossing the gate electrodes,
a data storage film between the semiconductor film and the gate electrodes,
a channel pad connected to one end of the semiconductor film, and
a lower surface of the first portion is lower than a lower surface of the channel pad based on the upper surface of the substrate.

10. The semiconductor memory device of claim 8, further comprising a division pattern extended in a second direction crossing the first direction and dividing the stacked structure,
wherein the division pattern includes a third portion having a first width and a fourth portion having a second width, the second width being greater than the first width.

11. The semiconductor memory device of claim 1, wherein the channel structure includes
a semiconductor film crossing the gate electrodes,
a data storage film between the semiconductor film and the gate electrodes,
a channel pad connected to one end of the semiconductor film, and
the upper surface of the dam structure is lower than a lower surface of the channel pad based on the upper surface of the substrate.

12. A semiconductor memory device comprising:
a substrate;
a stacked structure including a plurality of gate electrodes stacked on the substrate and spaced apart from each other in a first direction, the first direction being perpendicular to an upper surface of the substrate;
an interlayer insulating layer surrounding the stacked structure on the substrate;
a first channel structure extended in the first direction through the interlayer insulating layer and the stacked structure;
a dam structure extending in the first direction and surrounding at least a portion of the stacked structure in a plan view;
a capping insulating layer on the interlayer insulating layer, the first channel structure, and the dam structure; and
a second channel structure connected to the first channel structure, the second channel structure passing through the capping insulating layer,
wherein the dam structure is spaced apart from the capping insulating layer.

13. The semiconductor memory device of claim 12, further comprising an insulating pattern in the interlayer insulating layer, and
the insulating pattern is between the dam structure and the capping insulating layer.

14. The semiconductor memory device of claim 13, further comprising a dam contact connected to the dam structure,
the dam contact passing through the capping insulating layer and the insulating pattern.

15. The semiconductor memory device of claim 12, wherein the interlayer insulating layer includes
a dam hole extended in the first direction to expose the substrate, and
the dam structure fills at least a portion of the dam hole.

16. The semiconductor memory device of claim 12, further comprising a division pattern extending in a second direction, the second direction crossing the first direction and dividing the stacked structure,
wherein the division pattern includes
a first portion containing a first material,
a second portion on the first portion,
the second portion containing a second material,
the first material containing an insulating material, and
the second material containing at least one of an insulating material including carbon or silicon.

17. The semiconductor memory device of claim 12, further comprising a division pattern extending in a second direction and dividing the stacked structure, the second direction crossing the first direction,
wherein the division pattern includes a third portion having a first width and a fourth portion having a second width, the second width being greater than the first width.

18. An electronic system comprising:
a main board;
a semiconductor memory device including a peripheral circuit structure and a memory cell structure, the peripheral circuit structure and the memory cell structure being sequentially stacked on the main board; and
a controller electrically connected to the semiconductor memory device on the main board,
wherein the memory cell structure includes
a stacked structure including a plurality of gate electrodes stacked on the peripheral circuit structure and spaced apart from each other in a first direction,
a channel structure extending in the first direction and crossing the plurality of gate electrodes,
a gate contact passing through the stacked structure,
a dam structure spaced part from the gate contact in a second direction, the second direction crossing the first direction,
the dam structure surrounding at least a portion of the stacked structure in a plan view,
an interlayer insulating layer covering the stacked structure, the channel structure, and the gate contact, and
a height of a lower surface of the dam structure from a lower surface of the peripheral circuit structure is higher than a height of a lower surface of the channel structure from a lower surface of the peripheral circuit structure.

19. The electronic system of claim 18, further comprising
a capping insulating layer covering the interlayer insulating layer, the channel structure, the stacked structure, and the dam structure,
an insulating pattern between the capping insulating layer and the dam structure, and
a dam contact connected to the dam structure by passing through the capping insulating layer and the insulating pattern.

20. The electronic system of claim 18, further comprising a division pattern extending in the second direction crossing the first direction and dividing the stacked structure,
wherein the division pattern includes
a first portion containing a first material,
a second portion on the first portion,
the second portion containing a second material,
the first material containing an insulating material, and
the second material contains at least one of an insulating material including carbon or silicon.
